(19) United States
(12) Patent Application Publication
(10) Pub. No.: US 2024/0343949 A1
(43) Pub. Date: Oct. 17, 2024

(54) PRESSURE-SENSITIVE ADHESIVE SHEET

(71) Applicant: NITTO DENKO CORPORATION, Ibaraki-shi, Osaka (JP)

(72) Inventors: Kazumichi KATO, lbaraki-shi, Osaka (JP); Shusaku UENO, lbaraki-shi, Osaka (JP); Takamasa HIRAYAMA, lbaraki-shi, Osaka (JP)

(73) Assignee: NITTO DENKO CORPORATION, Ibaraki-shi, Osaka (JP)

(21) Appl. No.: 18/294,708

(22) PCT Filed: Dec. 16, 2021
(86) PCT No.: PCT/JP2021/046584

§ 371 Date: Feb. 2, 2024

(30) Foreign Application Priority Data
Sep. 17, 2021 (JP) 2021-152595

(51) Int. Cl. C09J 7/38; C09J 133/08

(52) U.S. Cl. CPC C09J 7/385; C09J 133/08; C09J 2203/326; C09J 2301/312; C09J 2467/006

(57) ABSTRACT

A pressure-sensitive adhesive sheet having a pressure-sensitive adhesive layer of which adhesive face has wettability difficult to change even when exposed to an atmospheric environment, and on which positional deviation or drop is difficult to occur in conveying an electronic component. The pressure-sensitive adhesive layer has an adhesive face protected by a release liner and has a displacement of water contact angles θ1 and θ2 against the adhesive face 10a under the following conditions T1 and T2 of 5° or less:
T1: immediately after separating the release liner R1 under an environment of 23° C.
T2: after 2 hour exposure of the adhesive face 10a to an atmospheric environment after separating the release liner R1 under an environment of 23° C.
θ1: water contact angle (°) of the adhesive face 10a under T1
θ2: water contact angle (°) of the adhesive face 10a under T2

Displacement R(°)=θ2−θ1.

### TECHNICAL FIELD

The present invention relates to a pressure-sensitive adhesive sheet. More specifically, the present invention relates to a pressure-sensitive adhesive sheet that can be suitably used for transfer of a compact electronic component such as a semiconductor chip, or an LED chip.

### BACKGROUND ART

In the production process of semiconductor devices, semiconductor wafers are generally divided into individual pieces by dicing in a state of being temporarily fixed on a dicing tape, and the semiconductor chips divided into individual pieces are pushed from the dicing tape side of the rear surface of the wafer by a pin member, picked up by a suction jig called a collet, and mounted on mounting substrates such as circuit boards (for example, Patent Literature 1).

However, advances in microfabrication technology have made semiconductor chips smaller and thinner, and it has become difficult to pick up such chips individually with a collet. Further, semiconductor devices have become smaller, which requires dense mounting of a large number of fine semiconductor chips on a mounting substrate, and there has been a problem that it is inefficient to mount these individually with a collet.

As means for solving the above-described problems, technique designated as laser transfer is being studied (see, for example, Patent Literature 2). In the laser transfer, compact (for example, a square with a side of 100 μm or less) electronic components such as semiconductor chips are disposed in a grid pattern on a temporary fixing material, and the resultant is disposed with the surface having the electronic components disposed thereon facing downward. Next, a substrate for transfer for transferring (receiving) the electronic components is disposed so as to face, with a gap provided therebetween, the surface of the temporary fixing material having the electronic components disposed thereon. Next, the electronic components are irradiated with a laser beam from the side of the temporary fixing material, and the temporary fixation is thus released to separate and drop, for transfer, the electronic components onto the substrate for transfer. The electronic components thus transferred to the substrate for transfer can be transferred to another carrier substrate to be mounted on a mounting substrate, or can be mounted on a mounting substrate by direct transfer from the substrate for transfer.

In the laser transfer, there is no need to pick up compact electronic components mechanically with a collet or the like, but the transfer can be performed under an optical time scale by irradiating a plurality of electronic components with a laser beam and sweeping the resultant, and hence the efficiency is remarkably improved. Since the temporary fixing material and the substrate for transfer are disposed with a gap (clearance) provided therebetween, it is advantageous also in that the electronic components can be arranged at intervals adjusted as desired.

In the laser transfer, since the temporary fixing material and the substrate for transfer are disposed with a gap (clearance) provided therebetween, there is a problem of a failure caused because a separated electronic component may be damaged due to impact applied thereto at collision to the substrate for transfer, may bounce to deviate its position, or may be turned upside down, and therefore, the surface of the substrate for transfer is required to have a shock absorbing property for reducing the impact applied at collision of an electronic component to the substrate for transfer. On the other hand, it is also required to have adhesiveness such that positional deviation or drop is not caused in conveying a received electronic component. Therefore, on the surface of the substrate for transfer, a pressure-sensitive adhesive layer having both a shock absorbing property and adhesiveness is provided (for example, Patent Literature 2).

### CITATION LIST

### Patent Literature

Patent Literature 1: Japanese Patent Application Laid-Open No. 2019-9203
Patent Literature 2: Japanese Patent Application Laid-Open No. 2019-067892

### SUMMARY OF INVENTION

### Technical Problem

The pressure-sensitive adhesive layer, the surface (adhesive face) of which is usually protected by a release liner, is used to be assembled on an apparatus after separating the release liner immediately before the use. In a state where the release liner is separated to expose the surface to an atmospheric environment, however, the wettability of the adhesive face is changed over time, which causes a problem that positional deviation or drop is caused in conveying an electronic component.

The present invention has been made in view of the above problems, and an object thereof is to provide a pressure-sensitive adhesive sheet having a pressure-sensitive adhesive layer of which adhesive face has wettability difficult to change even when exposed to an atmospheric environment, and on which positional deviation or drop is difficult to occur in conveying an electronic component.

### Solution to Problem

A first aspect of the present invention provides a pressure-sensitive adhesive sheet. The pressure-sensitive adhesive sheet according to the first aspect of the present invention comprises a pressure-sensitive adhesive layer having an adhesive face protected by a release liner.

In the present specification, the pressure-sensitive adhesive sheet according to the first aspect of the present invention is referred to as the “pressure-sensitive adhesive sheet of the present invention”, and the pressure-sensitive adhesive layer comprised in the pressure-sensitive adhesive sheet of the first aspect of the present invention is referred to as the “pressure-sensitive adhesive layer of the present invention” in some cases.

The pressure-sensitive adhesive sheet of the present invention can be favorably used for receiving an electronic component disposed on a temporary fixing material, and in more detail, is to be disposed so as to face, with a gap provided therebetween, a surface of a temporary fixing material having an electronic component disposed thereon so that it can be favorably used for receiving the electronic component. Accordingly, the pressure-sensitive adhesive layer of the pressure-sensitive adhesive sheet of the present invention (the pressure-sensitive adhesive layer of the present invention) has both a shock absorbing property for reducing impact caused in receiving the electronic component, and adhesiveness for preventing positional deviation or drop in conveying the received electronic component.

The pressure-sensitive adhesive layer of the present invention has the adhesive face protected by the release liner. The release liner is stacked on at least one adhesive face for protecting the shock absorbing property and the adhesiveness of the pressure-sensitive adhesive layer of the present invention, and is separated immediately before use of the pressure-sensitive adhesive sheet of the present invention for receiving the electronic component. There is, however, a problem that when the adhesive face is exposed to an atmospheric environment after separating the release liner, wettability of the adhesive face changes over time, and hence positional deviation or drop is caused in conveying the electronic component.

In the pressure-sensitive adhesive sheet of the present invention, the pressure-sensitive adhesive layer of the present invention has a displacement R of water contact angles θ₁ and θ₂ against the adhesive face under the following conditions T₁ and T₂ of 5° or less:
T₁: immediately after separating the release liner under an environment of 23° C.
T₂: after 2 hour exposure of the adhesive face to an atmospheric environment after separating the release liner under an environment of 23° C.
θ₁: water contact angle (°) of the adhesive face under T₁
θ₂: water contact angle (°) of the adhesive face under T₂

Displacement R(°)=θ₂−θ₁.

In the pressure-sensitive adhesive sheet of the present invention, the configuration in which the displacement R is 5° or less is favorable in that the wettability of the adhesive face is difficult to change over time even in a state where it is exposed to an atmospheric environment after separating the release liner, and hence positional deviation or drop can be prevented in conveying an electronic component.

In the pressure-sensitive adhesive sheet of the present invention, a ratio of a sinking depth of the pressure-sensitive adhesive layer, obtained by an iron ball drop test performed on the adhesive face of the pressure-sensitive adhesive layer of the present invention under the following condition, to the thickness of the pressure-sensitive adhesive layer (sinking depth/thickness×100) is preferably 15% or more.

Iron ball drop test: performed by dropping an iron ball of 1 g freely from a height of 1 m onto the adhesive face.

The configuration in which the ratio is 15% or more is preferable in that the pressure-sensitive adhesive layer of the present invention exhibits an excellent shock absorbing property, and hence can prevent a failure, in receiving an electronic component, of the electronic component being damaged, bouncing to deviate the position, or being turned upside down.

In the pressure-sensitive adhesive sheet of the present invention, release strength of the release liner from the adhesive face of the pressure-sensitive adhesive layer of the present invention is preferably not less than 0.15 N/50 mm and not more than 5 N/50 mm. The configuration in which the release strength of the release liner from the adhesive face is 0.15 N/50 mm or more is favorable in that even in the state where the displacement R is adjusted to 5° or less, and the adhesive face is exposed to an atmospheric environment after separating the release liner, the wettability of the adhesive face is difficult to change over time, and positional deviation or drop can be prevented in conveying an electronic component. On the other hand, the configuration in which the release strength of the release liner from the adhesive face is 5 N/50 mm or less is preferable in that the pressure-sensitive adhesive sheet of the present invention can be easily fixed on a carrier substrate or the like, and that the pressure-sensitive adhesive layer is prevented from being damaged.

In the pressure-sensitive adhesive sheet of the present invention, the thickness of the pressure-sensitive adhesive layer of the present invention is preferably not less than 1 μm and not more than 500 μm. The configuration in which the thickness of the pressure-sensitive adhesive layer of the present invention is 1 μm or more is preferable in that a shock absorbing property against impact of an electronic component is excellent. The configuration in which the thickness of the pressure-sensitive adhesive layer of the present invention is 500 μm or less is preferable from the viewpoint of transferability in transferring a received electronic component to another carrier substrate or mounting substrate.

In the pressure-sensitive adhesive sheet of the present invention, the pressure-sensitive adhesive layer of the present invention is preferably a pressure-sensitive adhesive layer formed from an acrylic pressure-sensitive adhesive composition. The configuration in which the pressure-sensitive adhesive layer of the present invention is formed from an acrylic pressure-sensitive adhesive composition is preferable in easiness of design of a pressure-sensitive adhesive for adjusting the displacement R to 5° or less, transparence, adhesiveness, cost and the like.

In the pressure-sensitive adhesive sheet of the present invention, the pressure-sensitive adhesive layer of the present invention may have a second pressure-sensitive adhesive layer stacked on a surface opposite to the adhesive face. This configuration is preferable in that the wettability of the adhesive face is difficult to change over time even when it is exposed to an atmospheric environment, that positional deviation or drop can be prevented in conveying an electronic component, and in addition, that the shock absorbing property in receiving the electronic component can be adjusted by the second pressure-sensitive adhesive layer stacked on the surface opposite to the adhesive face. The second pressure-sensitive adhesive layer can be laminated onto a base material included in a substrate for transfer, or a carrier substrate or the like.

In the pressure-sensitive adhesive sheet of the present invention, the pressure-sensitive adhesive layer (including a case where the second pressure-sensitive adhesive layer is stacked) may have a base material layer stacked on a surface opposite to the adhesive face. The pressure-sensitive adhesive layer of the present invention preferably has the base material layer on the surface opposite to the adhesive face in that stability and handleability in receiving an electronic component are improved.

In the pressure-sensitive adhesive sheet of the present invention, a second pressure-sensitive adhesive layer may be stacked on a surface of the base material layer on which the pressure-sensitive adhesive layer is not stacked. The second pressure-sensitive adhesive layer is preferably stacked on the surface of the base material layer on which the pressure-sensitive adhesive layer is not stacked from the viewpoint of workability because, for example, the second pressure-sensitive adhesive layer can be fixed on a carrier substrate.

The base material layer is preferably formed from a polyester film from the viewpoint of stability and handleability in receiving an electronic component.

### Advantageous Effects of Invention

In a pressure-sensitive adhesive layer included in a pressure-sensitive adhesive sheet of the present invention (pressure-sensitive adhesive layer of the present invention), even in a state where it is exposed to an atmospheric environment after separating a release liner, wettability of an adhesive face is difficult to change over time, and positional deviation or drop can be prevented in conveying an electronic component. Accordingly, the pressure-sensitive adhesive sheet of the present invention can be favorably used in laser transfer.

### BRIEF DESCRIPTION OF DRAWINGS

FIG. 1 is a schematic cross-sectional view showing one embodiment of a pressure-sensitive adhesive sheet of the present invention.

FIG. 2 is a schematic cross-sectional view showing another embodiment of the pressure-sensitive adhesive sheet of the present invention.

FIG. 3 is a schematic cross-sectional view showing another embodiment of the pressure-sensitive adhesive sheet of the present invention.

FIG. 4 is a schematic cross-sectional view showing another embodiment of the pressure-sensitive adhesive sheet of the present invention.

FIG. 5 is a schematic cross-sectional view showing one embodiment of a method for fixing the pressure-sensitive adhesive sheet of FIG. 1 on a carrier substrate.

FIG. 6 is a schematic cross-sectional view showing a first step in one embodiment of a processing method for an electronic component using the pressure-sensitive adhesive sheet fixed on the carrier substrate shown in FIG. 5.

FIG. 7 is a schematic cross-sectional view showing a second step and a third step in one embodiment of the processing method for an electronic component using the pressure-sensitive adhesive sheet fixed on the carrier substrate shown in FIG. 5.

### DESCRIPTION OF EMBODIMENTS

### (Pressure-Sensitive Adhesive Sheet of Invention)

A pressure-sensitive adhesive sheet of the present invention comprises a pressure-sensitive adhesive layer having an adhesive face protected by a release liner (pressure-sensitive adhesive of the present invention).

The pressure-sensitive adhesive sheet of the present invention is to be used in processing technique for transferring a compact electronic component, such as a semiconductor chip or an LED chip, to a mounting substrate such as a circuit substrate, and specifically used as a pressure-sensitive adhesive sheet for receiving an electronic component disposed on a temporary fixing material, more specifically, as a pressure-sensitive adhesive sheet to be disposed so as to face, with a gap provided therebetween, a surface of a temporary fixing material having an electronic component disposed thereon so that it can be favorably used for receiving the electronic component. When the pressure-sensitive adhesive sheet of the present invention is used for transfer of an electronic component, a plurality of electronic components can be disposed on a pressure-sensitive adhesive layer included in the pressure-sensitive adhesive sheet of the present invention under an optical time scale, and there is no need to individually pick them up. An electronic component disposed on the pressure-sensitive adhesive sheet of the present invention can be transferred to another carrier substrate to be mounted on a mounting substrate, or can be transferred from the pressure-sensitive adhesive layer of the present invention directly to a mounting substrate, and therefore, production efficiency can be remarkably improved. The pressure-sensitive adhesive sheet of the present invention comprises the pressure-sensitive adhesive layer that has both a shock absorbing property for reducing impact caused in receiving an electronic component, and adhesiveness for preventing positional deviation or drop in conveying the received electronic component.

The pressure-sensitive adhesive sheet of the present invention is not particularly limited in the form thereof as long as it comprises the adhesive face of the pressure-sensitive adhesive layer of the present invention (surface of the pressure-sensitive adhesive layer). For example, it may be a single-coated pressure-sensitive adhesive sheet having the adhesive face only on one surface, or may be a double-coated pressure-sensitive adhesive sheet having the adhesive face on both surfaces. When the pressure-sensitive adhesive sheet of the present invention is a double-coated pressure-sensitive adhesive sheet, the both adhesive faces of the double-coated pressure-sensitive adhesive sheet may be in the form provided by the pressure-sensitive adhesive layer of the present invention, or one of the adhesive faces may be in the form provided by the pressure-sensitive adhesive layer of the present invention with the other adhesive face in a form provided by another pressure-sensitive adhesive layer different from the pressure-sensitive adhesive layer of the present invention (in the present specification, sometimes referred to as the “second pressure-sensitive adhesive layer”).

The pressure-sensitive adhesive sheet of the present invention may be what is called a “base material-less type” pressure-sensitive adhesive sheet having no base material (base material layer), or may be a pressure-sensitive adhesive sheet of a type having a base material. In the present specification, a “base material-less type” pressure-sensitive adhesive sheet is referred to as a “base material-less pressure sensitive adhesive sheet” in some cases, and a pressure-sensitive adhesive sheet of a type having a base material is referred to as a “base material-attached pressure-sensitive adhesive sheet” in some cases. Examples of the base material-less pressure-sensitive adhesive sheet include a double-coated pressure-sensitive adhesive sheet including only the pressure-sensitive adhesive layer of the present invention, and a double-coated pressure-sensitive adhesive sheet including the pressure-sensitive adhesive layer of the present invention and a second pressure-sensitive adhesive layer (pressure-sensitive adhesive layer different from the pressure-sensitive adhesive layer of the present invention). Examples of the base material-attached pressure-sensitive adhesive sheet include a single-coated pressure-sensitive adhesive sheet having the pressure-sensitive adhesive layer of the present invention on one surface of a base material, a double-coated pressure-sensitive adhesive sheet having the pressure-sensitive adhesive layer of the present invention on both surfaces of a base material, and a double-coated pressure-sensitive adhesive sheet having the pressure-sensitive adhesive layer of the present invention on one surface side of a base material, and having a second pressure-sensitive adhesive layer on the other surface side thereof. The term “base material (base material layer)” refers to a support, and in using the pressure-sensitive adhesive sheet of the present invention, corresponds to a portion where an electronic component is received together with the pressure-sensitive adhesive layer. The release liner to be separated in using the pressure-sensitive adhesive layer is not encompassed in the base material. The term “pressure-sensitive adhesive sheet” has a meaning encompassing a “pressure-sensitive adhesive tape”. In other words, the pressure-sensitive adhesive sheet may be a pressure-sensitive adhesive tape in a form of a tape.

The adhesive face of the pressure-sensitive adhesive layer of the present invention (adhesive face for receiving an electronic component) is protected by a release liner. The release liner is stacked on at least one adhesive face for protecting the shock absorbing property and the adhesiveness of the pressure-sensitive adhesive layer of the present invention, and is separated immediately before using the pressure-sensitive adhesive sheet of the present invention for receiving an electronic component.

Embodiments of the pressure-sensitive adhesive sheet of the present invention will now be described below with reference to the accompanying drawings, and it is noted that the pressure-sensitive adhesive sheet of the present invention is not limited to these embodiments.

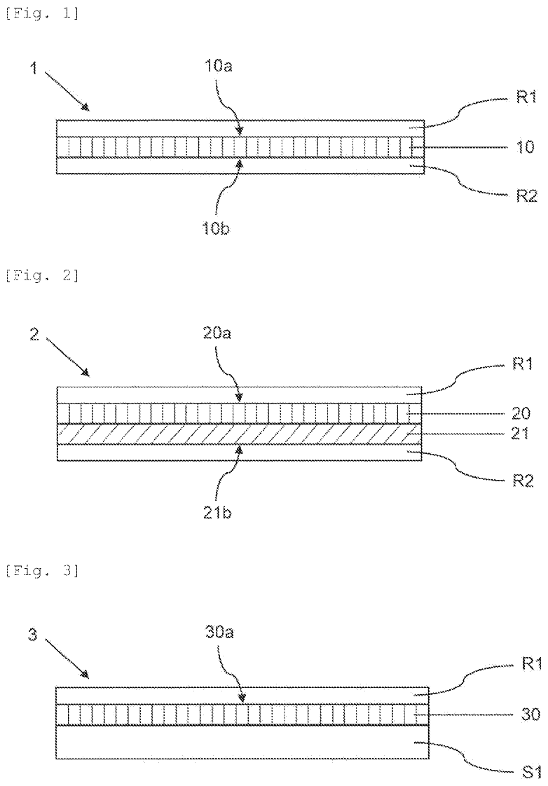

FIG. 1 is a schematic cross-sectional view showing one embodiment of the pressure-sensitive adhesive sheet of the present invention, wherein 1 denotes a pressure-sensitive adhesive sheet, 10 denotes a pressure-sensitive adhesive layer, and R1 and R2 denote release liners.

As shown in FIG. 1, the pressure-sensitive adhesive sheet 1 has a multilayer structure in which the release liner R1, the pressure-sensitive adhesive layer 10, and the release liner R2 are stacked in this order. The pressure-sensitive adhesive sheet 1 is used in processing technique for mounting a compact electronic component such as a semiconductor chip or an LED chip on a mounting substrate such as a circuit substrate. In the pressure-sensitive adhesive sheet 1, the pressure-sensitive adhesive layer 10 is formed from the pressure-sensitive adhesive layer of the present invention, and is favorably used for dissociating an electronic component disposed on a temporary fixing material, and receiving the dissociated electronic component. The release liner R1 is separated from the pressure-sensitive adhesive layer 10 before use, and an electronic component is received with the thus exposed adhesive face 10a. An adhesive face 10b exposed by separating the release liner R2 is laminated onto a base material included in a substrate for transfer, or a carrier substrate or the like.

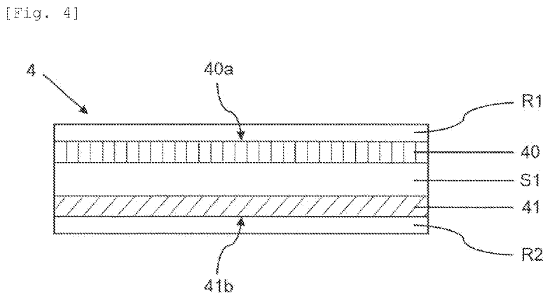

FIG. 2 is a schematic cross-sectional view showing another embodiment of the pressure-sensitive adhesive sheet of the present invention, wherein 2 denotes a pressure-sensitive adhesive sheet, 20 and 21 denote pressure-sensitive adhesive layers, and R1 and R2 denote release liners.

As shown in FIG. 2, the pressure-sensitive adhesive sheet 2 has a multilayer structure in which the release liner R1, the pressure-sensitive adhesive layer 20, the pressure-sensitive adhesive layer 21, and the release liner R2 are stacked in this order. The pressure-sensitive adhesive sheet 2 is used in processing technique for mounting a compact electronic component such as a semiconductor chip or an LED chip on a mounting substrate such as a circuit substrate. In the pressure-sensitive adhesive sheet 2, the pressure-sensitive adhesive layer 20 is formed from the pressure-sensitive adhesive layer of the present invention, and is favorably used for dissociating an electronic component disposed on a temporary fixing material, and receiving the dissociated electronic component. In the pressure-sensitive adhesive sheet 2, the pressure-sensitive adhesive layer 21 can adjust the shock absorbing property in receiving the electronic component together with the pressure-sensitive adhesive layer 20. The pressure-sensitive adhesive layer 21 may be formed from the pressure-sensitive adhesive layer of the present invention, or may be formed from a pressure-sensitive adhesive layer different from the pressure-sensitive adhesive layer of the present invention. The release liner R1 is separated from the pressure-sensitive adhesive layer 20 before use, and the electronic component is received with the thus exposed adhesive face 20a. An adhesive face 21b exposed by separating the release liner R2 is laminated onto a base material included in a substrate for transfer, or a carrier substrate or the like.

FIG. 3 is a schematic cross-sectional view showing another embodiment of the pressure-sensitive adhesive sheet of the present invention, wherein 3 denotes a pressure sensitive adhesive sheet, 30 denotes a pressure-sensitive adhesive layer, S1 denotes a base material, and R1 denotes a release liner.

As shown in FIG. 3, the pressure-sensitive adhesive sheet 3 has a multilayer structure in which the release liner R1, the pressure-sensitive adhesive layer 30, and the base material S1 are stacked in this order. The pressure-sensitive adhesive sheet 3 is used in processing technique for mounting a compact electronic component such as a semiconductor chip or an LED chip on a mounting substrate such as a circuit substrate. In the pressure-sensitive adhesive sheet 3, the pressure-sensitive adhesive layer 30 is formed from the pressure-sensitive adhesive layer of the present invention, and is favorably used for dissociating an electronic component disposed on a temporary fixing material, and receiving the dissociated electronic component. In the pressure-sensitive adhesive sheet 3, the base material S1 improves stability and handleability in receiving the electronic component. The release liner R1 is separated from the pressure-sensitive adhesive layer 30 before use, and the electronic component is received with the thus exposed adhesive face 30a.

FIG. 4 is a schematic cross-sectional view showing another embodiment of the pressure-sensitive adhesive sheet of the present invention, wherein 4 denotes a pressure-sensitive adhesive sheet, 40 and 41 denote pressure-sensitive adhesive layers, S1 denotes a base material, and R1 and R2 denote release liners.

As shown in FIG. 4, the pressure-sensitive adhesive sheet 4 has a multilayer structure in which the release liner R1, the pressure-sensitive adhesive layer 40, the base material S1, the pressure-sensitive adhesive layer 41, and the release liner R2 are stacked in this order. The pressure-sensitive adhesive sheet 4 is used in processing technique for mounting a compact electronic component such as a semiconductor chip or an LED chip on a mounting substrate such as a circuit substrate. In the pressure-sensitive adhesive sheet 4, the pressure-sensitive adhesive layer 40 is formed from the pressure-sensitive adhesive layer of the present invention, and is favorably used for dissociating an electronic component disposed on a temporary fixing material, and receiving the dissociated electronic component. In the pressure-sensitive adhesive sheet 4, the base material S1 improves stability and handleability in receiving the electronic component. In the pressure-sensitive adhesive sheet 4, the pressure-sensitive adhesive layer 41 can adjust the shock absorbing property in receiving the electronic component together with the pressure-sensitive adhesive layer 40. The pressure-sensitive adhesive layer 41 may be formed from the pressure-sensitive adhesive layer of the present invention, or may be formed from a pressure-sensitive adhesive layer different from the pressure-sensitive adhesive layer of the present invention. The release liner R1 is separated from the pressure-sensitive adhesive layer 40 before use, and the electronic component is received with the thus exposed adhesive face 40a. An adhesive face 41b exposed by separating the release liner R2 is laminated onto a base material included in a substrate for transfer, or a carrier substrate or the like.

Now, the respective configurations will be described.

### (Pressure-Sensitive Adhesive Layer of Invention)

In the pressure-sensitive adhesive sheet of the present invention, the pressure-sensitive adhesive layer of the present invention has a displacement R of water contact angles θ₁ and θ₂ against the adhesive face under the following conditions T₁ and T₂ of 5° or less:
T₁: immediately after separating the release liner under an environment of 23° C.
T₂: after 2 hour exposure of the adhesive face to an atmospheric environment after separating the release liner under an environment of 23° C.
θ₁: water contact angle (°) of the adhesive face under T₁
θ₂: water contact angle (°) of the adhesive face under T₂

Displacement R(°)=θ₂−θ₁.

In the pressure-sensitive adhesive sheet of the present invention, the configuration in which the displacement R is 5° or less is favorable in that the wettability of the adhesive face is difficult to change over time even in a state where it is exposed to an atmospheric environment after separating the release liner, and that positional deviation or drop can be prevented in conveying an electronic component. In that positional deviation or drop can be prevented in conveying an electronic component, the displacement R is preferably 4.5° or less, more preferably 4° or less, further preferably 3.5° or less, and may be 3° or less, 2.5° or less, 2° or less, or 1.5° or less.

Although the lower limit of the displacement R is not particularly limited, if the wettability of the adhesive face increases after exposing the adhesive face to an atmospheric environment, transferability of an electronic component to another carrier substrate or mounting substrate may decrease in some cases. From the viewpoint of the transferability of an electronic component, the displacement R is preferably −5° or more, more preferably −4° or more, and further preferably −3° or more.

In the pressure-sensitive adhesive layer of the present invention, the water contact angle θ₁ is preferably 120° or less, and more preferably 118° or less in that positional deviation or drop in conveying an electronic component can be prevented. From the viewpoint of the transferability of an electronic component, the water contact angle θ₁ is preferably 110° or more, and more preferably 111° or more.

The water contact angle, and the displacement R thereof are specifically measured by methods described in Examples below. The water contact angle, and the displacement R can be adjusted by adjusting the type and composition (monomer composition) of a pressure-sensitive adhesive composition contained in the pressure-sensitive adhesive layer of the present invention, the type and amount of a crosslinking agent, the thickness of the pressure-sensitive adhesive layer, the type of the release liner (more accurately, the type and amount of a release agent), and the like.

A ratio of a sinking depth of the pressure-sensitive adhesive layer of the present invention, obtained by an iron ball drop test performed on the adhesive face of the pressure-sensitive adhesive layer of the present invention under the following condition, to the thickness of the pressure-sensitive adhesive layer (sinking depth/thickness×100) is preferably 15% or more.

Iron ball drop test: performed by dropping an iron ball of 1 g freely from a height of 1 m onto the adhesive face.

The configuration in which the ratio (sinking depth/thickness×100) is 15% or more indicates that the pressure-sensitive adhesive layer of the present invention has an excellent shock absorbing property, and is favorable in that a failure, in receiving an electronic component, of the electronic component being damaged, bouncing to deviate the position, or being turned upside down can be prevented. From the viewpoint of an excellent shock absorbing property of the pressure-sensitive adhesive layer of the present invention, the ratio is more preferably 17% or more, further preferably 20% or more, and particularly preferably 30% or more. From the viewpoint of the transferability of an electronic component to another carrier substrate or mounting substrate, the ratio (sinking depth/thickness×100) is preferably 95% or less, and more preferably 90% or less.

In the iron ball drop test, the measurement is specifically performed by a method described in Examples below. The ratio (sinking depth/thickness×100) obtained in the iron drop test can be adjusted by adjusting the type and composition (monomer composition) of the pressure-sensitive adhesive composition contained in the pressure-sensitive adhesive layer of the present invention, the type and amount of the crosslinking agent, the thickness of the pressure-sensitive adhesive layer, and the like.

Initial adhesive strength to stainless steel at normal temperature of the adhesive face of the pressure-sensitive adhesive layer of the present invention is preferably 0.1 N/20 mm or more. The configuration in which the initial adhesive strength is 0.1 N/20 mm or more is preferable in that positional deviation and turning-over otherwise caused by bounce of an electronic component at the time of collision can be suppressed. In that the positional deviation and turning-over of an electronic component can be suppressed, the initial adhesive strength is more preferably 0.2 N/20 mm or more, and may be 0.3 N/20 mm or more. The upper limit of the initial adhesive strength is not particularly limited, and from the viewpoint of the transferability of a received electronic component to another carrier substrate or mounting substrate, is preferably 10 N/20 mm or less, more preferably 9 N/20 mm or less, and further preferably 7 N/20 mm or less. The initial adhesive strength refers to adhesive strength before irradiation with radiation.

Adhesive strength at normal temperature to stainless steel of the adhesive face of the pressure-sensitive adhesive layer of the present invention after irradiation with radiation is preferably 0.01 N/20 mm or more. The configuration in which the adhesive strength after irradiation with radiation is 0.01 N/20 mm or more is preferable in that a received electronic component is held with positional deviation suppressed in conveyance to a next step or the like, and the adhesive strength after irradiation with radiation is more preferably 0.03 N/20 mm or more, and further preferably 0.05 N/20 mm or more. From the viewpoint of the transferability of a received electronic component to another carrier substrate or mounting substrate, the adhesive strength after irradiation with radiation is preferably 2 N/20 mm or less, and more preferably 1.5 N/20 mm or less.

The initial adhesive strength, and the adhesive strength after irradiation with radiation can be measured, for example, by adhesive strength measurement described in Examples below, and can be adjusted by adjusting the type and composition (monomer composition) of the pressure-sensitive adhesive composition contained in the pressure-sensitive adhesive layer of the present invention, the type and amount of the crosslinking agent, the thickness of the pressure-sensitive adhesive layer, the type and amount of a photopolymerization initiator, and the like.

The thickness of the pressure-sensitive adhesive layer of the present invention is preferably not less than 1 μm and not more than 500 μm. The configuration in which the thickness of the pressure-sensitive adhesive layer of the present invention is 1 μm or more is preferable in preventing missing of the pressure-sensitive adhesive from the pressure-sensitive adhesive layer, and the like. From the viewpoint of the shock absorbing property against collision of an electronic component, the thickness of the pressure-sensitive adhesive layer of the present invention is preferably 5 μm or more, and may be 10 μm or more, 20 μm or more, or 30 μm or more. The configuration in which the thickness of the pressure-sensitive adhesive layer of the present invention is 500 μm or less is preferable from the viewpoint of the transferability in transferring an electronic component to another carrier substrate or mounting substrate, and the thickness may be 400 μm or less, or 300 μm or less. When the pressure-sensitive adhesive layer of the present invention has a multilayer structure including a second pressure-sensitive adhesive layer, the thickness of the pressure-sensitive adhesive layer refers to the thickness of the whole multilayer structure.

When the pressure-sensitive adhesive layer of the present invention has a multilayer structure including the second pressure-sensitive adhesive layer, the thickness of the pressure-sensitive adhesive layer excluding the second pressure-sensitive adhesive layer is preferably not less than 1 μm and not more than 50 μm. The configuration in which the thickness of the pressure-sensitive adhesive layer of the present invention is 1 μm or more is preferable from the viewpoint of suppressing change of the wettability of the adhesive face, and the thickness is preferably 2 μm or more, and more preferably 5 μm or more. The configuration in which the thickness of the pressure-sensitive adhesive layer of the present invention is 50 μm or less is preferable from the viewpoint of the transferability in transferring an electronic component to another carrier substrate or mounting substrate, and the thickness may be 40 μm or less, or 30 μm or less.

An initial probe tack value at normal temperature of the pressure-sensitive adhesive layer of the present invention is preferably not less than 5 N/cm² and not more than 42 N/cm². The configuration in which the initial probe tack value is 5 N/cm² or more is preferable in that impact caused by collision of an electronic component and the like to the pressure-sensitive adhesive layer can be sufficiently absorbed, and that positional deviation or turning-over caused by bounce of the electronic component at collision can be suppressed. In that positional deviation and turning-over of an electronic component can be suppressed, the initial probe tack value is preferably 8 N/cm² or more, and may be 10 N/cm² or more, or 12 N/cm² or more. The configuration in which the probe tack value is 42 N/cm² or less is preferable from the viewpoint of preventing the pressure-sensitive adhesive from sticking to or leaving an adhesive residue on the received electronic component, and the probe tack value may be 40 N/cm² or less, or 35 N/cm² or less. The initial probe tack value refers to a probe tack value of the adhesive face immediately after separating the release liner.

A change rate of a probe tack value obtained after 2 hour exposure of the adhesive face to an atmospheric environment to the initial probe tack value of the pressure-sensitive adhesive layer of the present invention is preferably more than −14%. The configuration in which the change rate of the probe tack value is more than −14% is preferable in that drop and positional deviation of an electronic component can be suppressed at the time of conveyance. In that drop and positional deviation of an electronic component can be suppressed, the change rate of the probe tack value is preferably −10% or more, and more preferably −8% or more. The upper limit of the change rate of the probe tack value is not particularly limited, and from the viewpoint of the transferability in transferring a received electronic component to another carrier substrate or mounting substrate, is preferably 10% or less, and preferably 5% or less. The probe tack value after 2 hour exposure to an atmospheric environment refers to a probe tack value of the adhesive face obtained after exposure to an atmospheric environment for 2 hours after separating the release liner. The change rate of the probe tack value is obtained in accordance with the following equation:
P₀: initial probe tack value
P₂: probe tack value after 2 hour exposure to an atmospheric environment

Change rate of probe tack value=(P₁−P₀)/P₀×100

The initial probe tack value, the probe tack value after 2 hour exposure to an atmospheric environment, and the change rate thereof, specifically, can be measured by methods described in Examples below, and can be adjusted by adjusting the type and composition (monomer composition) of the pressure-sensitive adhesive composition contained in the pressure-sensitive adhesive layer of the present invention, the type and amount of the crosslinking agent, the thickness of the pressure-sensitive adhesive layer, the type of the release liner (more accurately, the type and amount of the release agent) and the like.

A ratio, to the thickness of the pressure-sensitive adhesive layer, of a sinking depth obtained by thermomechanical analysis (TMA) of the pressure-sensitive adhesive layer of the present invention under the following conditions (sinking depth/thickness×100) is preferably 10% or more.

### Thermomechanical Analysis (TMA)

Probe diameter: 1.0 mm
Mode: penetration mode
Indentation load: 0.05 N
Ambient temperature in measurement: −40° C.
Indentation load time: 20 min

In a laser transfer step, since the transfer of an electronic component is completed under an optical time scale, a shock absorption characteristic of the pressure-sensitive adhesive under this time scale is significant. Specifically, the optical time scale is correlated to a frequency for sweeping a laser beam, and for example, is 100 kHz or the like. An adhesive physical property in a frequency region of 100 kHz corresponds to an adhesive physical property in a low temperature region of −40° C. based on temperature-time conversion rule, and therefore, larger deformation caused under a load applied to the pressure-sensitive adhesive in this temperature region means a more excellent shock absorption characteristic. For example, the ratio (sinking depth/thickness×100) obtained by applying a load to the pressure-sensitive adhesive layer at −40° C. in the thermomechanical analysis (TMA) can be used as an index of the shock absorption characteristic.

The configuration in which the ratio (sinking depth/thickness×100) obtained by the thermomechanical analysis (TMA) at −40° C. is 10% or more is preferable in that even if the pressure-sensitive adhesive layer is thin, impact caused by collision of an electronic component or the like can be sufficiently absorbed, and the electronic component can be received without damage or positional deviation. In that the impact caused by collision of an electronic component or the like can be sufficiently absorbed, the ratio is preferably 15% or more, and may be 20% or more, 30% or more, 40% or more, 50% or more, 60% or more, 70% or more, or 80% or more. From the viewpoint of the transferability of a received electronic component to another carrier substrate or mounting substrate, the ratio is preferably 95% or less, and may be 90% or less.

The ratio (sinking depth/thickness×100) can be adjusted by adjusting the type and composition (monomer composition) of the pressure-sensitive adhesive composition contained in the pressure-sensitive adhesive layer of the present invention, the type and amount of the crosslinking agent, the thickness of the pressure-sensitive adhesive layer, and the like.

In the laser transfer step, since the transfer of an electronic component is completed under an optical time scale, the shock absorption characteristic of the pressure-sensitive adhesive under this time scale is significant. Specifically, the optical time scale is correlated to a frequency for sweeping a laser beam, and for example, is 100 kHz or the like. It is about 10 microseconds in terms of time scale, and the pressure-sensitive adhesive needs to deform in response to impact under this time scale.

A common logarithm (Log₁₀ G′) of a storage modulus (Pa) at a frequency of 100 kHz and 25° C. of the pressure-sensitive adhesive layer of the present invention is preferably 7.5 or less. The configuration in which the common logarithm of the storage modulus is 7.5 or less is preferable in that the impact caused by collision of an electronic component or the like to the pressure-sensitive adhesive layer can be sufficiently absorbed, and that positional deviation and turning-over otherwise caused by bounce of the electronic component at the time of collision can be suppressed. From the viewpoint of the shock absorbing property against collision of an electronic component, the common logarithm of the storage modulus is preferably 7.4 or less, or may be 7.3 or less, 7.2 or less, 7.1 or less, or 7 or less. From the viewpoint of preventing positional shift in conveying an electronic component received on the pressure-sensitive adhesive layer of the present invention, the common logarithm of the storage modulus is preferably 4 or more, and may be 5 or more.

A loss tangent (tan δ) at a frequency of 100 kHz and 25° C. of the pressure-sensitive adhesive layer of the present invention is preferably 0.8 or more. The configuration in which the loss tangent is 0.8 or more is preferable in that the pressure-sensitive adhesive layer exhibits excellent attenuation under an optical time scale, that the impact caused by collision of an electronic component or the like to the pressure-sensitive adhesive layer can be sufficiently absorbed, and that positional deviation and turning-over otherwise caused by bounce of the electronic component at the time of collision can be suppressed. From the viewpoint of the shock absorbing property against collision of an electronic component, the loss tangent is preferably 0.95 or more, and may be 1.2 or more. From the viewpoint of preventing positional shift in conveying an electronic component received on the pressure-sensitive adhesive layer of the present invention, the loss tangent is preferably 2.8 or less, and may be 2.3 or less.

The adhesive physical property in a frequency region of 100 kHz corresponds to the adhesive physical property in a low temperature region of −40° C. based on temperature-time conversion rule, and therefore, the shock absorption characteristic of the pressure-sensitive adhesive in this temperature region is also similarly significant.

The common logarithm (Log₁₀ G′) of a storage modulus (Pa) at a frequency of 1 Hz and −40° C. of the pressure-sensitive adhesive layer is preferably 8.5 or less. The configuration in which the common logarithm of the storage modulus is 8.5 or less is preferable in that the impact caused by collision of an electronic component or the like to the pressure-sensitive adhesive layer can be sufficiently absorbed, and that positional deviation and turning-over otherwise caused by bounce of the electronic component at the time of collision can be suppressed. From the viewpoint of the shock absorbing property against collision of an electronic component, the common logarithm of the storage modulus is preferably 8.4 or less, or may be 8.3 or less, 8.2 or less, 8.1 or less, or 8 or less. From the viewpoint of preventing positional shift in conveying an electronic component received on the pressure-sensitive adhesive layer of the present invention, the common logarithm of the storage modulus is preferably 4 or more, and may be 5 or more.

The loss tangent (tan δ) at a frequency of 1 Hz and −40° C. of the pressure-sensitive adhesive layer of the present invention is preferably 0.1 or more. The configuration in which the loss tangent is 0.1 or more is preferable in that the pressure-sensitive adhesive layer exhibits excellent attenuation at a low temperature, that the impact caused by collision of an electronic component or the like to the pressure-sensitive adhesive layer can be sufficiently absorbed, and that positional deviation and turning-over otherwise caused by bounce of the electronic component at the time of collision can be suppressed. From the viewpoint of the shock absorbing property against collision of an electronic component, the loss tangent is preferably 0.2 or more, and may be 0.3 or more, 0.4 or more, or 0.5 or more. From the viewpoint of preventing positional shift in conveying an electronic component received on the pressure-sensitive adhesive sheet, the loss tangent is preferably 2.2 or less, and may be 1.7 or less.

The common logarithm of the storage modulus, and the loss tangent can be measured by, for example, dynamic viscoelasticity measurement, and can be adjusted by adjusting the type and composition (monomer composition) of the pressure-sensitive adhesive composition contained in the pressure-sensitive adhesive layer of the present invention, the type and amount of the crosslinking agent, and the like.

### (Pressure-Sensitive Adhesive Composition of Invention)

The pressure-sensitive adhesive composition contained in the pressure-sensitive adhesive layer of the present invention (in the present specification, sometimes referred to as the “pressure-sensitive adhesive composition of the present invention”) is not particularly limited, and examples thereof include an acrylic pressure-sensitive adhesive, a rubber-based pressure-sensitive adhesive, a vinyl alkyl ether-based pressure-sensitive adhesive, a silicone-based pressure-sensitive adhesive, a polyester-based pressure-sensitive adhesive, a polyamide-based pressure-sensitive adhesive, a urethane-based pressure-sensitive adhesive, a fluorine-based pressure-sensitive adhesive, and an epoxy-based pressure-sensitive adhesive. As the pressure-sensitive adhesive composition of the present invention, an acrylic pressure-sensitive adhesive and a silicone-based pressure-sensitive adhesive are preferable, and in particular, an acrylic pressure-sensitive adhesive is preferable in the above-described various desired physical properties of the pressure-sensitive adhesive layer of the present invention, particularly, easiness of design of the pressure-sensitive adhesive for adjusting the displacement R to 5° or less, transparency, adhesiveness, and cost. In other words, the pressure-sensitive adhesive layer of the present invention is preferably an acrylic pressure-sensitive adhesive layer containing an acrylic pressure-sensitive adhesive composition. One of these pressure-sensitive adhesives can be used singly, or in a combination of two or more thereof.

The acrylic pressure-sensitive adhesive composition contains an acrylic polymer as a base polymer. The acrylic polymer refers to a polymer containing, as a monomer component constituting the polymer, an acrylic monomer (monomer having a (meth)acryloyl group in a molecule). The acrylic polymer is preferably a polymer containing, as a monomer component constituting the polymer, an alkyl (meth)acrylate. Acrylic polymers can be used singly, or in a combination of two or more thereof.

The pressure-sensitive adhesive composition of the present invention may be in any form. The pressure-sensitive adhesive composition may be, for example, an emulsion type, a solvent type (solution type), an active energy ray curing type, a heat melt type (hot melt type) or the like. In particular, a solvent type or active energy ray curing type pressure-sensitive adhesive composition is preferable in productivity, and in that a pressure-sensitive adhesive layer excellent in optical characteristics and appearance can be easily obtained. In particular, from the viewpoint that impact caused by collision of an electronic component can be absorbed, and that positional deviation and turning-over of the electronic component can be suppressed, a solvent type pressure-sensitive adhesive composition is preferable.

Specifically, the pressure-sensitive adhesive layer of the present invention is preferably an acrylic pressure-sensitive adhesive layer containing an acrylic polymer as a base polymer, and formed from a solvent type acrylic pressure-sensitive adhesive composition.

Examples of the active energy ray include ionizing radiation such as an α ray, a β ray, a γ ray, a neutron ray, and an electron ray, and an ultraviolet ray, and an ultraviolet ray is particularly preferable. In other words, the active energy ray curing type pressure-sensitive adhesive composition is preferably an ultraviolet curing type pressure-sensitive adhesive composition.

Examples of the acrylic pressure-sensitive adhesive composition include an acrylic pressure-sensitive adhesive composition containing an acrylic polymer as an essential component, and an acrylic pressure-sensitive adhesive composition containing, as an essential component, a mixture of monomers (sometimes referred to as a “monomer mixture”) contained in an acrylic polymer, or a partial polymer thereof. An example of the former includes what is called a solvent type acrylic pressure-sensitive adhesive composition. An example of the latter includes what is called an active energy ray curing type acrylic pressure-sensitive adhesive composition. The term “monomer mixture” means a mixture containing monomer components constituting a polymer. The term “partial polymer”, which is sometimes referred to as a “prepolymer”, means a composition in which one, two or more monomer components out of the monomer components of the monomer mixture are partially polymerized.

The acrylic polymer refers to a polymer constituted (formed) by using an acrylic monomer as an essential monomer component. The acrylic polymer is preferably a polymer constituted (formed) by using an alkyl (meth)acrylate as an essential monomer component. In other words, the acrylic polymer preferably contains an alkyl (meth)acrylate as a structural unit. In the present specification, the term “(meth)acrylic” means “acrylic” and/or “methacrylic” (one or both of “acrylic” and “methacrylic”), and the same applies to others. The acrylic polymer contains one, two or more monomer components.

Preferable examples of the alkyl (meth)acrylate used as the essential monomer component include alkyl (meth)acrylates having a linear or branched alkyl group. The alkyl (meth)acrylates can be used singly, or in a combination of two or more thereof.

The alkyl (meth)acrylates having a linear or branched alkyl group are not particularly limited, and examples include alkyl (meth)acrylates having a linear or branched alkyl group having 1 to 20 carbon atoms, such as methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, t-butyl (meth)acrylate, pentyl (meth)acrylate, isopentyl (meth)acrylate, hexyl (meth)acrylate, heptyl (meth)acrylate, octyl (meth)acrylate, 2-ethylhexyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate (lauryl (meth)acrylate), tridecyl (meth)acrylate, tetradecyl (meth)acrylate, pentadecyl (meth)acrylate, hexadecyl (meth)acrylate, heptadecyl (meth)acrylate, octadecyl (meth)acrylate (stearyl (meth)acrylate), isostearyl (meth)acrylate, nonadecyl (meth)acrylate, and eicosyl (meth)acrylate. In particular, the alkyl (meth)acrylate having a linear or branched alkyl group is preferably an alkyl (meth)acrylate having a linear or branched alkyl group having 4 to 18 carbon atoms, and more preferably 2-ethylhexyl acrylate (2EHA), n-butyl acrylate (BA), lauryl acrylate (LA), or lauryl methacrylate (LMA). The alkyl (meth)acrylates having a linear or branched alkyl group can be used singly, or in a combination of two or more thereof.

A ratio of the alkyl (meth)acrylate in all monomer components (100% by weight) constituting the acrylic polymer is not particularly limited, and from the viewpoint that impact caused by collision of an electronic component can be absorbed, and that positional deviation and turning-over of an electronic component can be suppressed, from the viewpoint that drop and positional deviation of an electronic component under conveyance can be suppressed, and from the viewpoint of controlling the various properties (particularly, the shock absorbing property), the ratio is preferably 80% by weight or more, and may be 85% by weight or more, or 90% by weight or more. The upper limit of the ratio of the alkyl (meth)acrylate is also not particularly limited, and may be 99% by weight or less, or 98% by weight or less.

The acrylic polymer may contain, together with the alkyl (meth)acrylate, a copolymerizable monomer as a monomer component constituting the polymer. In other words, the acrylic polymer may contain a copolymerizable monomer as a structural unit. Copolymerizable monomers can be used singly, or in a combination of two or more thereof.

The copolymerizable monomer is not particularly limited, and preferable examples thereof include a monomer having a hydroxyl group in a molecule, and a monomer having a carboxyl group in a molecule in that such a monomer can be a reactive site with a crosslinking agent described below, or an isocyanate compound or the like containing both an ultraviolet ray polymerizable carbon-carbon double bond and an isocyanate group working as a second functional group, and in controlling transparency and adhesiveness, or the like. In other words, the acrylic polymer preferably contains, as a structural unit, a monomer having a hydroxyl group in a molecule. The acrylic polymer preferably contains, as a structural unit, a monomer having a carboxyl group in a molecule.

The monomer having a hydroxyl group in a molecule refers to a monomer having at least one hydroxyl group in a molecule (in one molecule), and a preferable example includes one having a polymerizable functional group having an unsaturated double bond such as a (meth)acryloyl group or a vinyl group, and having a hydroxyl group. In the present specification, the “monomer having a hydroxyl group in a molecule” is sometimes referred to as the “hydroxyl group-containing monomer”. Hydroxyl group-containing monomers can be used singly, or in a combination of two or more thereof.

Examples of the hydroxyl group-containing monomer include hydroxyl group-containing (meth)acrylates such as 2-hydroxyethyl (meth)acrylate, 2-hydroxypropyl (meth)acrylate, 3-hydroxypropyl (meth)acrylate, 4-hydroxybutyl (meth)acrylate, 6-hydroxyhexyl (meth)acrylate, hydroxyoctyl (meth)arylate, hydroxydecyl (meth)acrylate, hydroxylauryl (meth)acrylate, and 4-hydroxymethylcyclohexyl (meth)acrylate; vinyl alcohol; and allyl alcohol.

In particular, the hydroxyl group-containing monomer is preferably a hydroxyl group-containing (meth)acrylate, and more preferably 2-hydroxyethyl acrylate (HEA), and 4-hydroxybutyl acrylate (4HBA).

When the acrylic polymer contains the hydroxyl group-containing monomer as the monomer component constituting the polymer, a ratio of the hydroxyl group-containing monomer in all the monomer components (100% by weight) constituting the acrylic polymer is not particularly limited, and is preferably 0.5% by weight or more, more preferably 0.8% by weight or more, and further preferably 1% by weight of more in that such a monomer can be a reactive site with a crosslinking agent described below, or an isocyanate compound or the like containing both an ultraviolet polymerizable carbon-carbon double bond and an isocyanate group working as a second functional group, in controlling the degree of crosslinking and radiation curability, in controlling transparency, adhesiveness, and the like. The upper limit of the ratio of the hydroxyl group-containing monomer is preferably 20% by weight or less, more preferably 18% by weight or less, and further preferably 15% by weight or less.

The monomer having a carbonyl group in a molecule refers to a monomer having at least one carboxyl group in a molecule (in one molecule), and a preferable example includes one having a polymerizable functional group having an unsaturated double bond such as a (meth)acryloyl group or a vinyl group, and having a carboxyl group. In the present specification, the “monomer having a carboxyl group in a molecule” is sometimes referred to as the “carboxyl group-containing monomer”. Carboxyl group-containing monomers can be used singly, or in a combination of two or more thereof.

Examples of the carboxyl group-containing monomer include (meth)acrylic acid, itaconic acid, maleic acid, fumaric acid, crotonic acid, and isocrotonic acid. The carboxyl group-containing monomer encompasses an acid anhydride group-containing monomer such as maleic anhydride, or itaconic anhydride.

In particular, the carboxyl group-containing monomer is preferably (meth)acrylic acid, and more preferably acrylic acid (AA).

When the acrylic polymer contains the carboxyl group-containing monomer as the monomer component constituting the polymer, a ratio of the carboxyl group-containing monomer in all the monomer components (100% by weight) constituting the acrylic polymer is not particularly limited, and is preferably 0.5% by weight or more, more preferably 0.8% by weight or more, and further preferably 1% by weight of more in that such a monomer can be a reactive site with a crosslinking agent described below, or an isocyanate compound or the like containing both an ultraviolet polymerizable carbon-carbon double bond and an isocyanate group working as a second functional group, in controlling the degree of crosslinking and radiation curability, in controlling transparency and adhesiveness, and the like. The upper limit of the ratio of the carboxyl group-containing monomer is preferably 20% by weight or less, more preferably 18% by weight or less, and further preferably 15% by weight or less.

A total ratio of the hydroxyl group-containing monomer and the carboxyl group-containing monomer in all the monomer components (100% by weight) constituting the acrylic polymer is not particularly limited, and is preferably 1% by weight or more, and more preferably 3% by weight or more in that such a monomer can be a reactive site with a crosslinking agent described below, or an isocyanate compound or the like containing both an ultraviolet polymerizable carbon-carbon double bond and an isocyanate group working as a second functional group, in controlling transparency and adhesiveness, and the like. The upper limit of the total ratio is preferably 20% by weight or less, and more preferably 15% by weight or less in obtaining a pressure-sensitive adhesive layer having adequate flexibility, and obtaining a pressure-sensitive adhesive layer excellent in transparency.

Besides, an example of the copolymerizable monomer includes a polyfunctional monomer. Examples of the polyfunctional monomer include hexanediol di(meth)acrylate, butanediol di(meth)acrylate, (poly)ethylene glycol di(meth)acrylate, (poly)propylene glycol di(meth)acrylate, neopentyl glycol di(meth)acrylate, pentaerythritol di(meth)acrylate, pentaerythritol tri(meth)acrylate, dipentaerytritol hexa(meth)acrylate, trimethylol propane tri(meth)acrylate, tetramethylol methanetri(meth)acrylate, allyl (meth)acrylate, vinyl (meth)acrylate, divinyl benzene, epoxy acrylate, polyester acrylate, and urethane acrylate. The polyfunctional monomers can be used singly, or in a combination of two or more thereof.

When the acrylic polymer contains the polyfunctional monomer as the monomer component constituting the polymer, a ratio of the polyfunctional monomer in all the monomer components (100% by weight) constituting the acrylic polymer is not particularly limited, and is preferably 0.5% by weight or less (for example, more than 0% by weight and not more than 0.5% by weight), and more preferably 0.2% by weight or less (for example, more than 0% by weight and not more than 0.2% by weight).

The acrylic polymer may contain a monomer unit derived from one, two or more other monomers copolymerizable with (meth)acrylate from the viewpoint of, for example, improving cohesive strength, heat resistance, and the like. Examples of other copolymerizable monomers for forming the monomer unit of the acrylic polymer include a nitrogen-containing monomer, an alicyclic structure-containing monomer, an epoxy group-containing monomer, a sulfonic acid group-containing monomer, and a phosphoric acid group-containing monomer. Examples of the nitrogen-containing monomer include acryloylmorpholine, acrylamide, N-vinylpyrrolidone, and acrylonitrile. Examples of the alicyclic structure-containing monomer include cyclopropyl (meth)acrylate, cyclobutyl (meth)acrylate, cyclopentyl (meth)acrylate, cyclohexyl (meth)acrylate, cycloheptyl (meth)acrylate, cyclooctyl (meth)acrylate, isobornyl (meth)acrylate, and dicyclopentanyl (meth)acrylate. Examples of the epoxy group-containing monomer include glycidyl (meth)acrylate and methylglycidyl (meth)acrylate. Examples of the sulfonic acid group-containing monomer include styrene sulfonic acid, allyl sulfonic acid, 2-(meth)acrylamide-2-methylpropane sulfonic acid, (meth)acrylamide propane sulfonic acid, and (meth)acryloyloxy naphthalene sulfonic acid. An example of the phosphoric acid group-containing monomer includes 2-hydroxyethylacryloyl phosphate.

Although not particularly limited, the acrylic polymer preferably contains, as the monomer component constituting the polymer, a monomer having a low glass transition temperature (Tg) when formed as a homopolymer (hereinafter, sometimes referred to as the “low Tg monomer”). The low Tg monomer is preferably used as the monomer component from the viewpoint that the pressure-sensitive adhesive containing the acrylic polymer is soft, the various properties (particularly, the shock absorbing property) of the pressure-sensitive adhesive layer of the present invention are controlled, and hence, impact caused by collision of the electronic component can be absorbed to suppress positional deviation and turning-over of an electronic component, and that drop and positional deviation of the electronic component under conveyance can be suppressed.

The glass transition temperature of the low Tg monomer formed as a homopolymer is not particularly limited, and is, for example, 0° C. or less, and is preferably −10° C. or less, and more preferably −25° C. or less. When the Tg of the low Tg monomer falls in this range, the shock absorbing property of the pressure-sensitive adhesive layer is increased.

The low Tg monomer may be any of the monomers described above as the examples of the monomer included in the monomer component constituting the acrylic polymer, or another monomer. In particular, the monomer component constituting the acrylic polymer preferably contains a monomer component that is a monomer described above as an example of the monomer component constituting the acrylic polymer, and is a low Tg monomer. The low Tg monomers used may be one, or two or more.

The low Tg monomer is not particularly limited, and preferable examples thereof include 2-ethylhexyl acrylate (EHA, Tg of homopolymer: −70° C.), butyl acrylate (BA, Tg of homopolymer: −55° C.), lauryl methacrylate (LMA, Tg of homopolymer: −65° C.), lauryl acrylate (LA, Tg of homopolymer: −23° C.), and isononyl acrylate (iNAA, Tg of homopolymer: −58° C.), and 2-ethylhexyl acrylate, butyl acrylate, and lauryl methacrylate are preferable.

When the acrylic polymer contains the low Tg monomer as the monomer component constituting the polymer, a ratio of the low Tg monomer in all the monomer components (100% by weight) constituting the acrylic polymer is not particularly limited, and is preferably 80% by weight or more, and may be 85% by weight or more, or 90% by weight or more. The upper limit of the ratio of the low Tg monomer is also not particularly limited, and may be 99% by weight or less, or 98% by weight or less. The ratio of the low Tg monomer preferably falls in this range from the viewpoint that the various properties (particularly, the shock absorbing property) are controlled, that impact caused in collision of an electronic component is absorbed, that positional deviation and turning-over of an electronic component can be suppressed, and that drop and positional deviation of the electronic component under conveyance can be suppressed. When two or more low Tg monomers are contained in the monomer components constituting the polymer, the “ratio of the low Tg monomer” refers to a total ratio of the two or more low Tg monomers.

A content of the base polymer (particularly, the acrylic polymer) in the pressure-sensitive adhesive layer of the present invention is not particularly limited, and is preferably 50% by weight or more (for example, 50 to 100% by weight), more preferably 80% by weight or more (for example, 80 to 100% by weight), and further preferably 90% by weight or more (for example, 90 to 100% by weight) based on the total weight of 100% by weight of the pressure-sensitive adhesive layer of the present invention.

The base polymer, such as the acrylic polymer, contained in the pressure-sensitive adhesive composition of the present invention is obtained by polymerizing monomer components. This polymerization method is not particularly limited, and examples include a solution polymerization method, an emulsion polymerization method, a bulk polymerization method, and a polymerization method by active energy ray irradiation (active energy ray polymerization method). In particular, the solution polymerization method and the active energy ray polymerization method are preferable, and the solution polymerization method is more preferable in transparency of the pressure-sensitive adhesive layer, cost, and the like.

In the polymerization of the monomer components, various general solvents may be used. Examples of the solvents include organic solvents including esters such as ethyl acetate and n-butyl acetate; aromatic hydrocarbons such as toluene and benzene; aliphatic hydrocarbons such as n-hexane and n-heptane; alicyclic hydrocarbons such as cyclohexane and methyl cyclohexane; and ketones such as methyl ethyl ketone and methyl isobutyl ketone. The solvents can be used singly, or in a combination of two or more thereof.

In the polymerization of the monomer components, a polymerization initiator such as a thermal polymerization initiator or a photopolymerization initiator (photoinitiator) may be used in accordance with the type of the polymerization reaction. Polymerization initiators can be used singly, or in a combination of two or more thereof.

The thermal polymerization initiator is not particularly limited, and examples thereof include an azo-based polymerization initiator, a peroxide-based polymerization initiator (such as dibenzoyl peroxide, or tert-butyl permaleate), and a redox-based polymerization initiator. In particular, the peroxide-based polymerization initiator is preferable. Examples of the azo-based polymerization initiator include 2,2′-azobisisobutyronitrile (hereinafter, sometimes referred to as “AIBN”), 2,2′-azobis-2-methylbutyronitrile (hereinafter, sometimes referred to as “AMBN”), dimethyl 2,2′-azobis(2-methylpropionate), and 4,4′-azobis-4-cyanovaleric acid. Thermal polymerization initiators can be used singly, or in a combination of two or more thereof.

The amount of the thermal polymerization initiator used is not particularly limited, and for example, is preferably 0.05 parts by weight or more, more preferably 0.1 parts by weight or more, and preferably 0.5 parts by weight or less, and more preferably 0.3 parts by weight or less based on 100 parts by weight of all the monomer components constituting the acrylic polymer.

The photopolymerization initiator is not particularly limited, and examples thereof include a benzoin ether-based photopolymerization initiator, an acetophenone-based photopolymerization initiator, an α-ketol-based photopolymerization initiator, an aromatic sulfonyl chloride-based photopolymerization initiator, a photoactive oxime-based photopolymerization initiator, a benzoin-based photopolymerization initiator, a benzyl-based photopolymerization initiator, a benzophenone-based photopolymerization initiator, a ketal-based photopolymerization initiator, and a thioxanthone-based photopolymerization initiator. Other examples include an acylphosphine oxide-based photopolymerization initiator, and a titanocene-based photopolymerization initiator. Examples of the benzoin ether-based photopolymerization initiator include benzoin methyl ether, benzoin ethyl ether, benzoin propyl ether, benzoin isopropyl ether, benzoin isobutyl ether, 2,2-dimethoxy-1,2-diphenylethan-1-on, and anisole methyl ether. Examples of the acetophenone-based photopolymerization initiator include 2,2-diethoxyacetophenone, 2,2-dimethoxy-2-phenylacetophenone, 1-hydroxycyclohexylphenylketone, 4-phenoxydichloroacetophenone, and 4-(t-butyl)dichloroacetophenone. Examples of the α-ketol-based photopolymerization initiator include 2-methyl-2-hydroxypropiophenone, and 1-[4-(2-hydroxyethyl)phenyl]-2-methylpropan-1-on. An example of the aromatic sulfonyl chloride-based photopolymerization initiator includes 2-naphthalene sulfonyl chloride. An example of the photoactive oxime-based photopolymerization initiator includes 1-phenyl-1,1-propanedione-2-(0-ethoxycarbonyl)-oxime. An example of the benzoin-based photopolymerization initiator includes benzoin. An example of the benzyl-based photopolymerization initiator includes benzyl. Examples of the benzophenone-based photopolymerization initiator include benzophenone, benzoylbenzoic acid, 3,3′-dimethyl-4-methoxybenzophenone, polyvinyl benzophenone, and α-hydroxycyclohexylphenylketone. An example of the ketal-based photopolymerization initiator includes benzyl dimethyl ketal. Examples of the thioxanthone-based photopolymerization initiator include thioxanthone, 2-chlorothioxanthone, 2-methylthioxanthone, 2,4-dimethylthioxanthone, isopropylthioxanthone, 2,4-diisopropylthioxanthone, and dodecylthioxanthone. Examples of the acylphosphine oxide-based photopolymerization initiator include 2,4,6-trimethylbenzoyl-diphenyl-phosphine oxide, and bis(2,4,6-trimethylbenzoyl)-phenyl phosphine oxide. An example of the titanocene-based photopolymerization initiator includes bis(η⁵-2,4-cyclopentadien-1-yl)-bis(2,6-difluoro-3-(1H-pyrrol-1-yl)phenyl)titanium. The photopolymerization initiators can be used singly, or in a combination of two or more thereof.

When the photopolymerization initiator is used in the polymerization of the acrylic polymer, the amount of the photopolymerization initiator used is not particularly limited, and is, for example, preferably 0.01 parts by weight or more, more preferably 0.1 parts by weight or more, and preferably 3 parts by weight or less, and more preferably 1.5 parts by weight or less based on 100 parts by weight of all the monomer components constituting the acrylic polymer.

Although not particularly limited, a crosslinking agent may be used for forming the pressure-sensitive adhesive layer of the present invention. For example, the various properties described above (particularly, the displacement R and the shock absorbing property) can be controlled from the viewpoint that the acrylic polymer used in the acrylic pressure-sensitive adhesive layer is crosslinked, that the impact caused by collision of an electronic component can be absorbed to suppress positional deviation and turning-over of the electronic component, and that drop and positional deviation of the electronic component under conveyance can be suppressed. Crosslinking agents can be used singly, or in a combination of two or more thereof.

The crosslinking agent is not particularly limited, and examples thereof include an isocyanate-based crosslinking agent, an epoxy-based crosslinking agent, a melamine-based crosslinking agent, a peroxide-based crosslinking agent, a urea-based crosslinking agent, a metal alkoxide-based crosslinking agent, a metal chelate-based crosslinking agent, a metal salt-based crosslinking agent, a carbodiimide-based crosslinking agent, an oxazoline-based crosslinking agent, an aziridine-based crosslinking agent, and an amine-based crosslinking agent. In particular, an isocyanate-based crosslinking agent and an epoxy-based crosslinking agent are preferable, and an isocyanate-based crosslinking agent is more preferable.

Examples of the isocyanate-based crosslinking agent (polyfunctional isocyanate compound) include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisocyanate. Besides, examples of the isocyanate-based crosslinking agent also include commercially available products such as a trimethylol propane/tolylene diisocyanate adduct (trade name “Coronate L”, manufactured by Nippon Polyurethane Industry Co., Ltd.), a trimethylol propane/hexamethylene diisocyanate adduct (trade name “Coronate HL”, manufactured by Nippon Polyurethane Industry Co., Ltd.), and a trimethylol propane/xylylene diisocyanate adduct (trade name “Takenate D-110N”, manufactured by Mitsui Chemicals, Inc.).

Examples of the epoxy-based crosslinking agent (polyfunctional epoxy compound) include N,N,N′,N′-tetraglycidyl-m-xylenediamine, diglycidylaniline, 1,3-bis(N,N-diglycidylaminomethyl)cyclohexane, 1,6-hexanediol diglycidyl ether, neopentyl glycol diglycidyl ether, ethylene glycol diglycidyl ether, propylene glycol diglycidyl ether, polyethylene glycol diglycidyl ether, polypropylene glycol diglycidyl ether, sorbitol polyglycidyl ether, glycerol polyglycidyl ether, pentaerythritol polyglycidyl ether, polyglycerol polyglycidyl ether, sorbitan polyglycidyl ether, trimethylolpropane polyglycidyl ether, diglycidyl adipate, diglycidyl o-phthalate, triglycidyl-tris(2-hydroxyethyl)isocyanurate, resorcin diglycidyl ether, bisphenol-S-diglycidyl ether, and in addition, epoxy-based resins having two or more epoxy groups in a molecule. Besides, an example of the epoxy-based crosslinking agent also includes a commercially available product under the trade name “Tetrad C” (manufactured by Mitsubishi Gas Chemical Company, Inc.).

When a crosslinking agent is used for the formation of the pressure-sensitive adhesive layer of the present invention, the amount of the crosslinking agent used is not particularly limited, and is preferably 0.01 parts by weight or more, and more preferably 0.01 parts by weight or more based on 100 parts by weight of the base polymer in controlling the various properties described above (particularly, the displacement R, and the shock absorbing property) from the viewpoint that impact caused by collision of an electronic component can be absorbed to suppress positional deviation and turning-over of the electronic component, and from the viewpoint that drop and positional deviation of the electronic component under conveyance can be suppressed. The upper limit of the amount used is preferably 10 parts by weight or less, and more preferably 5 parts by weight or less based on 100 parts by weight of the base polymer in obtaining appropriate flexibility in the pressure-sensitive adhesive layer to improve the adhesiveness.

Although not particularly limited, the acrylic pressure-sensitive adhesive composition of the present invention may contain a crosslinking accelerator. The type of crosslinking accelerator can be appropriately selected according to the type of crosslinking agent to be used. In the present specification, the term “crosslinking accelerator” refers to a catalyst that increases the rate of the crosslinking reaction by the crosslinking agent. Examples of such a crosslinking accelerator include tin(Sn)-containing compounds such as dioctyltin dilaurate, dibutyltin dilaurate, dibutyltin diacetate, dibutyltin diacetylacetonate, tetra-n-butyltin, and trimethyltin hydroxide; amines such as N,N,N′,N′-tetramethylhexanediamine, and triethylamine; and N-containing compounds such as imidazoles. Among them, Sn-containing compounds are preferred. The use of these crosslinking accelerators is particularly effective when a hydroxyl group-containing monomer is used as the secondary monomer and an isocyanate-based crosslinking agent is used as the crosslinking agent. The amount of the crosslinking accelerator contained in the pressure-sensitive adhesive composition may be, for example, about 0.01 to 0.5 parts by mass (preferably about 0.01 to 0.1 parts by mass) based on 100 parts by mass of the acrylic polymer.

The pressure-sensitive adhesive layer of the present invention may be a pressure-sensitive adhesive layer whose adhesive strength can be intentionally reduced by an external action (an adhesive strength reducible pressure-sensitive adhesive layer), or a pressure-sensitive adhesive layer whose adhesive strength is hardly reduced or not reduced at all by an external action (an adhesive strength non-reducible pressure-sensitive adhesive layer), which can be appropriately selected according to the method, conditions, and the like for mounting an electronic component.

When the pressure-sensitive adhesive layer of the present invention is an adhesive strength reducible pressure-sensitive adhesive layer, it is possible to selectively use a state in which the pressure-sensitive adhesive layer of the present invention exhibits relatively high adhesive strength and a state in which it exhibits relatively low adhesive strength. For example, in a step in which the pressure-sensitive adhesive layer of the present invention receives (transfers) an electronic component, it is possible to sufficiently absorb impact caused by collision of an electronic component or the like to the pressure-sensitive adhesive layer to suppress positional deviation and turning-over otherwise caused by bounce of the electronic component at the time of collision by utilizing the state in which the pressure-sensitive adhesive layer of the present invention exhibits relatively high adhesive strength. On the other hand, in the subsequent process of transferring the received electronic component to another carrier substrate or mounting substrate, the adhesive strength of the pressure-sensitive adhesive layer of the present invention can be reduced to improve transferability (deliverability), and suppress an adhesive residue from being left on the electronic component.

Examples of the pressure-sensitive adhesive for forming such an adhesive strength reducible pressure-sensitive adhesive layer include a radiation-curable pressure-sensitive adhesive and a heat-expandable pressure-sensitive adhesive, and a radiation-curable pressure-sensitive adhesive is preferable in handleability. In other words, the pressure-sensitive adhesive layer of the present invention is formed preferably from a radiation-curable pressure-sensitive adhesive. As the pressure-sensitive adhesive for forming the adhesive strength reducible pressure-sensitive adhesive layer, one kind of pressure-sensitive adhesive may be used, or two or more kinds of pressure-sensitive adhesives may be used.

As the radiation-curable pressure-sensitive adhesive, for example, a pressure-sensitive adhesive of a type that is cured by irradiation with an electron beam, ultraviolet rays, α-rays, β-rays, γ-rays, or X-rays can be used, and a pressure-sensitive adhesive of a type that is cured by ultraviolet irradiation (ultraviolet-curable pressure-sensitive adhesive) can be particularly preferably used.

Examples of the radiation-curable pressure-sensitive adhesive include an addition-type radiation-curable pressure-sensitive adhesive containing a base polymer such as an acrylic polymer and a radiation-polymerizable monomer component or oligomer component having a functional group such as a radiation-polymerizable carbon-carbon double bond. As the base polymer, an acrylic polymer similar to that described above can be used.

Examples of the radiation-polymerizable monomer component include urethane (meth)acrylate, trimethylolpropane tri(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butanediol di(meth)acrylate. Examples of the radiation-polymerizable oligomer component include various oligomers such as urethane-based, polyether-based, polyester-based, polycarbonate-based, and polybutadiene-based oligomers, and those having a molecular weight of about 100 to 30,000 are preferred. The content of the radiation-curable monomer component and oligomer component in the radiation-curable pressure-sensitive adhesive forming the pressure-sensitive adhesive layer of the present invention is, for example, about 5 to 500 parts by mass, preferably 40 to 150 parts by mass, based on 100 parts by mass of the base polymer. Further, as the addition-type radiation-curable pressure-sensitive adhesive, for example, those disclosed in Japanese Patent Application Laid-open No. 60-196956 may be used.

Examples of the radiation-curable pressure-sensitive adhesive also include an intrinsic radiation-curable pressure-sensitive adhesive containing a base polymer having a functional group such as a radiation-polymerizable carbon-carbon double bond in a polymer side chain, inside the polymer main chain, or at the end of the polymer main chain. When such an intrinsic radiation-curable pressure-sensitive adhesive is used, unintended changes over time in pressure-sensitive adhesive properties due to the movement of low-molecular-weight components within the formed pressure-sensitive adhesive layer tend to be suppressed.

The base polymer contained in the intrinsic radiation-curable pressure-sensitive adhesive is preferably an acrylic polymer. Examples of a method for introducing a radiation-polymerizable carbon-carbon double bond into an acrylic polymer include a method in which a raw material monomer containing a monomer component having a first functional group is polymerized (copolymerized) to obtain an acrylic polymer, and then a compound having a second functional group capable of reacting with the first functional group and a radiation-polymerizable carbon-carbon double bond is subjected to a condensation reaction or an addition reaction with the acrylic polymer while maintaining the radiation-polymerizability of the carbon-carbon double bond.

Examples of the combination of the first functional group and the second functional group include a carboxy group and an epoxy group, an epoxy group and a carboxy group, a carboxy group and an aziridyl group, an aziridyl group and a carboxy group, a hydroxy group and an isocyanate group, and an isocyanate group and a hydroxy group. Among these, a combination of a hydroxy group and an isocyanate group and a combination of an isocyanate group and a hydroxy group are preferred from the viewpoint of ease of reaction tracking. In particular, a combination in which the first functional group is a hydroxy group and the second functional group is an isocyanate group is preferred, from the viewpoint that it is technically difficult to produce a polymer having a highly reactive isocyanate group, while it is easy to produce and obtain an acrylic polymer having a hydroxy group. Examples of the compound having an isocyanate group and a radiation-polymerizable carbon-carbon double bond, that is, the radiation-polymerizable unsaturated functional group-containing isocyanate compound include methacryloyl isocyanate, 2-methacryloyloxyethyl isocyanate, and m-isopropenyl-α,α-dimethylbenzyl isocyanate. Further, examples of the acrylic polymer having a hydroxy group include those containing structural units derived from the hydroxy group-containing monomer described above or an ether-based compound such as 2-hydroxyethyl vinyl ether, 4-hydroxybutyl vinyl ether, and diethylene glycol monovinyl ether.

When the radiation-polymerizable unsaturated functional group-containing isocyanate compound is used, a content of the radiation-polymerizable unsaturated functional group-containing isocyanate compound in the radiation-curable pressure-sensitive adhesive for forming the pressure-sensitive adhesive layer of the present invention is, for example, 5 to 100 parts by mass, and preferably about 7 to 50 parts by mass based on 100 parts by mass of the base polymer.

The radiation-curable pressure-sensitive adhesive preferably contains a photopolymerization initiator. Examples of the photopolymerization initiator include α-ketol-based compounds, acetophenone-based compounds, benzoin ether-based compounds, ketal-based compounds, aromatic sulfonyl chloride-based compounds, photoactive oxime-based compounds, benzophenone-based compounds, thioxanthone-based compounds, camphorquinone, halogenated ketone, acylphosphinoxides, and acylphosphonate. Examples of the α-ketol-based compound include 4-(2-hydroxyethoxy)phenyl(2-hydroxy-2-propyl)ketone, α-hydroxy-α,α′-dimethylacetophenone, 2-methyl-2-hydroxypropiophenone, 1-hydroxycyclohexylphenylketone, and 2-hydroxy-1-(4-(4-(2-hydroxy-2-methylpropionyl)benzyl)phenyl)-2-methylpropan-1-on. Examples of the acetophenone-based compounds include methoxyacetophenone, 2,2-dimethoxy-2-phenylacetophenone, 2,2-diethoxyacetophenone, and 2-methyl-1-[4-(methylthio)-phenyl]-2-morpholinopropane-1. Examples of the benzoin ether-based compounds include benzoin ethyl ether, benzoin isopropyl ether, and anisoin methyl ether. Examples of the ketal-based compounds include benzyl dimethyl ketal. Examples of the aromatic sulfonyl chloride-based compounds include 2-naphthalenesulfonyl chloride. Examples of the photoactive oxime-based compounds include 1-phenyl-1,2-propanedione-2-(0-ethoxycarbonyl)oxime. Examples of the benzophenone-based compounds include benzophenone, benzoylbenzoic acid, and 3,3′-dimethyl-4-methoxybenzophenone. Examples of the thioxanthone-based compounds include thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropyl thioxanthone. The content of the photopolymerization initiator in the radiation-curable pressure-sensitive adhesive is, for example, 0.05 to 20 parts by mass based on 100 parts by mass of the base polymer.

The heat-foaming pressure-sensitive adhesive is a pressure-sensitive adhesive containing a component (for example, foaming agent, thermally expandable microspheres) that foams or expands when heated. Examples of the foaming agent include various inorganic foaming agents and organic foaming agents. Examples of the inorganic foaming agent include ammonium carbonate, ammonium hydrogencarbonate, sodium hydrogencarbonate, ammonium nitrite, sodium borohydride, and azides. Examples of the organic foaming agent include chlorinated fluoroalkanes such as trichloromonofluoromethane and dichloromonofluoromethane; azo-based compounds such as azobisisobutyronitrile, azodicarbonamide, and barium azodicarboxylate; hydrazine-based compounds such as paratoluenesulfonyl hydrazide, diphenylsulfone-3,3′-disulfonyl hydrazide, 4,4′-oxybis(benzenesulfonyl hydrazide), and allylbis(sulfonyl hydrazide); semicarbazide-based compounds such as p-toluylenesulfonyl semicarbazide and 4,4′-oxybis(benzenesulfonyl semicarbazide); triazole-based compounds such as 5-morpholyl-1,2,3,4-thiatriazole; and N-nitroso-based compounds such as N,N′-dinitrosopentamethylenetetramine and N,N′-dimethyl-N,N′-dinitrosoterephthalamide. Examples of the thermally expandable microspheres include microspheres having a structure in which a substance that easily gasifies and expands upon heating is encapsulated in the shell. Examples of the substance that easily gasifies and expands upon heating include isobutane, propane, and pentane. Thermally expandable microspheres can be produced by encapsulating a substance that easily gasifies and expands upon heating in a shell-forming substance by a coacervation method, an interfacial polymerization method, or the like. As the shell-forming substance, a substance exhibiting thermal meltability and a substance capable of bursting due to the action of thermal expansion of the encapsulated substance can be used. Examples of such substances include vinylidene chloride-acrylonitrile copolymer, polyvinyl alcohol, polyvinyl butyral, polymethyl methacrylate, polyacrylonitrile, polyvinylidene chloride, and polysulfone.

Examples of the adhesive strength non-reducible pressure-sensitive adhesive layer include a pressure-sensitive-type pressure-sensitive adhesive layer. The pressure-sensitive-type pressure-sensitive adhesive layer includes a pressure-sensitive adhesive layer in a form in which the pressure-sensitive adhesive layer formed from the radiation-curable pressure-sensitive adhesive described above with respect to the adhesive strength reducible pressure-sensitive adhesive layer is cured in advance by irradiation with radiation while having a certain adhesive strength. As the pressure-sensitive adhesive for forming the adhesive strength non-reducible pressure-sensitive adhesive layer, one kind of pressure-sensitive adhesive may be used, or two or more kinds of pressure-sensitive adhesives may be used. Further, the entire pressure-sensitive adhesive layer of the present invention may be an adhesive strength non-reducible pressure-sensitive adhesive layer, or a part thereof may be an adhesive strength non-reducible pressure-sensitive adhesive layer. For example, when the pressure-sensitive adhesive layer of the present invention has a single-layer structure, the entire pressure-sensitive adhesive layer of the present invention may be an adhesive strength non-reducible pressure-sensitive adhesive layer, or a specific portion of the pressure-sensitive adhesive layer of the present invention may be an adhesive strength non-reducible pressure-sensitive adhesive layer and the other portion may be an adhesive strength reducible pressure-sensitive adhesive layer. Further, when the pressure-sensitive adhesive layer of the present invention has a multilayer structure, all the pressure-sensitive adhesive layers in the multilayer structure may be adhesive strength non-reducible pressure-sensitive adhesive layers, or some of the pressure-sensitive adhesive layers in the multilayer structure may be adhesive strength non-reducible pressure-sensitive adhesive layers.

The pressure-sensitive adhesive layer (radiation-irradiated radiation-curable pressure-sensitive adhesive layer) in a form in which the pressure-sensitive adhesive layer formed from the radiation-curable pressure-sensitive adhesive (radiation-unirradiated radiation-curable pressure-sensitive adhesive layer) is cured in advance by irradiation with radiation exhibits adhesiveness due to the contained polymer component even when the adhesive strength is reduced by irradiation with radiation, and can exhibit the minimum adhesive strength required for the pressure-sensitive adhesive layer of the present invention. When a radiation-irradiated radiation-curable pressure-sensitive adhesive layer is used, the entire pressure-sensitive adhesive layer of the present invention may be a radiation-irradiated radiation-curable pressure-sensitive adhesive layer, or a part of the pressure-sensitive adhesive layer of the present invention may be a radiation-irradiated radiation-curable pressure-sensitive adhesive layer and the other part may be a radiation-unirradiated radiation-curable pressure-sensitive adhesive layer, in the surface spreading direction of the pressure-sensitive adhesive layer of the present invention. In the present specification, the “radiation-curable pressure-sensitive adhesive layer” refers to a pressure-sensitive adhesive layer formed from a radiation-curable pressure-sensitive adhesive, and includes both a radiation-unirradiated radiation-curable pressure-sensitive adhesive layer having radiation curability and a radiation-cured radiation-curable pressure-sensitive adhesive layer obtained by curing the pressure-sensitive adhesive layer by irradiation with radiation.

As the pressure-sensitive adhesive forming the pressure-sensitive-type pressure-sensitive adhesive layer, a known or commonly used pressure-sensitive-type pressure-sensitive adhesive can be used, and an acrylic pressure-sensitive adhesive having an acrylic polymer as a base polymer can be preferably used. When the pressure-sensitive adhesive layer of the present invention contains an acrylic polymer as a pressure-sensitive-type pressure-sensitive adhesive, the acrylic polymer is preferably a polymer containing a structural unit derived from a (meth)acrylic acid ester as a structural unit in the highest proportion by mass. As the acrylic polymer, for example, the acrylic polymer described as the acrylic polymer that can be contained in the addition-type radiation-curable pressure-sensitive adhesive can be adopted.

The silicone-based pressure-sensitive adhesive is not particularly limited, and a known or commonly used silicone-based pressure-sensitive adhesive can be used, and for example, an addition-type silicone-based pressure-sensitive adhesive, a peroxide-curable silicone-based pressure-sensitive adhesive, and a condensation-type silicone-based pressure-sensitive, or the like can be used. The silicone-based pressure-sensitive adhesive may be of one-liquid type or two-liquid type. The silicone-based pressure-sensitive adhesives can be used alone or in combination of two or more kinds thereof.

The addition-type silicone-based pressure-sensitive adhesive is generally a pressure-sensitive adhesive that produces a silicone-based polymer by subjecting an organopolysiloxane having an alkenyl group such as a vinyl group on a silicon atom and an organopolysiloxane having a hydrosilyl group to an addition reaction (hydrosilylation reaction) using a platinum compound catalyst such as chloroplatinic acid. The peroxide-curable silicone-based pressure-sensitive adhesive is generally a pressure-sensitive adhesive that produces a silicone-based polymer by curing (crosslinking) an organopolysiloxane with a peroxide. Further, the condensation-type silicone-based pressure-sensitive adhesive is generally a pressure-sensitive adhesive that produces a silicone-based polymer by a dehydration or dealcoholization reaction between polyorganosiloxanes having a hydrolyzable silyl group such as a silanol group or an alkoxysilyl group at the end.

An example of the silicone-based pressure-sensitive adhesive includes a silicone-based pressure-sensitive adhesive composition containing a silicone rubber and a silicone resin in that such a composition can be easily controlled to have low adhesiveness and low tackiness, and from the viewpoint that the change over time of the wettability of the adhesive face can be suppressed to suppress drop and positional deviation of an electronic component under conveyance.

The silicone rubber is not particularly limited as long as it is a silicone-based rubber component, and for example, an organopolysiloxane having dimethylsiloxane, methylphenylsiloxane, or the like as a main structural unit can be used. Further, depending on the type of reaction, a silicone-based rubber having an alkenyl group bonded to a silicon atom (an alkenyl group-containing organopolysiloxane; in the case of an addition reaction type), a silicone-based rubber having at least a methyl group (in the case of peroxide-curable type), a silicone-based rubber having a silanol group or a hydrolyzable alkoxysilyl group at an end (in the case of a condensation type), or the like can be used. The weight-average molecular weight of the organopolysiloxane in the silicone rubber is usually 150,000 or more, preferably 280,000 to 1,000,000, and particularly preferably 500,000 to 900,000.

Further, the silicone resin is not particularly limited as long as it is a silicone-based resin used in a silicone-based pressure-sensitive adhesive, and examples thereof include a silicone resin comprising an organopolysiloxane formed of a (co)polymer having at least one unit selected from an M unit formed of a structural unit “R₃Si_{1/2}”, a Q unit formed of a structural unit “SiO₂”, a T unit formed of a structural unit “RSiO_{3/2}”, and a D unit formed of a structural unit “R₂SiO”. R in the structural unit represents a hydrocarbon group or a hydroxyl group. Examples of the hydrocarbon group include aliphatic hydrocarbon groups (for example, alkyl groups such as methyl group and ethyl group), alicyclic hydrocarbon groups (for example, cycloalkyl groups such as cyclohexyl group), and aromatic hydrocarbon groups (for example, aryl groups such as phenyl group and naphthyl group). The ratio between the M unit and at least one unit selected from Q unit, T unit and D unit is desirably, for example, about the former/latter (molar ratio)=0.3/1 to 1.5/1 (preferably 0.5/1 to 1.3/1). Various functional groups such as a vinyl group may be introduced into the organopolysiloxane in such a silicone resin, if necessary. The functional group to be introduced may be a functional group capable of causing a crosslinking reaction. The silicone resin is preferably an MQ resin formed of M units and Q units. The weight-average molecular weight of the organopolysiloxane in the silicone resin is usually 1,000 or more, preferably 1,000 to 20,000, and particularly preferably 1,500 to 10,000.

The mixing ratio of the silicone rubber and the silicone resin is not particularly limited, but is preferably, for example, 100 to 220 parts by weight (particularly, 120 to 180 parts by weight) of the silicone resin based on 100 parts by weight of the silicone rubber, from the viewpoint of easily controlling to have low adhesiveness and low tackiness.

In the silicone-based pressure-sensitive adhesive composition containing a silicone rubber and a silicone resin, the silicone rubber and the silicone resin may be in a mixed state in which they are simply mixed, or may react with each other to form a condensate (particularly, partial condensate), a crosslinking reaction product, an addition reaction product, or the like.

As an addition-type silicone-based pressure-sensitive adhesive, for example, those under the trade name “SD4580”, the trade name “SD4584”, the trade name “SD4585”, the trade name “SD4587L”, the trade name “SD4560”, the trade name “SD4570”, the trade name “SD4600FC”, the trade name “SD4593”, and the trade name “SE1700” (all manufactured by Dow Toray Co., Ltd.); and the trade name “KR-3700”, the trade name “KR-3701”, the trade name “X-40-3237-1”, the trade name “X-40-3240”, the trade name “X-40-3291-1”, and the trade name “X-40-3306” (all manufactured by Shin-Etsu Chemical Co., Ltd.) are commercially available. Besides, as a peroxide-curable silicone-based pressure-sensitive adhesive, for example, those under the trade name “KR-100”, the trade name “KR-101-10”, and the trade name “KR-130” (all manufactured by Shin-Etsu Chemical Co., Ltd.) are commercially available.

The silicone-based pressure-sensitive adhesive composition containing a silicone rubber and a silicone resin preferably contains a crosslinking agent in that such a composition can be easily controlled to have low adhesiveness and low tackiness, and from the viewpoint that the change over time of the wettability of the adhesive face can be suppressed to suppress drop and positional deviation of an electronic component under conveyance. The wettability of the adhesive face changes over time in the state exposed to an atmospheric environment after separating the release liner probably because a release agent contained in a release layer formed on the surface of the release liner moves to the pressure-sensitive adhesive layer, and the release agent having moved to the pressure-sensitive adhesive layer bleeds out on the surface of the adhesive face. Accordingly, when the silicone rubber and the silicone resin of the silicone-based pressure sensitive adhesive layer are crosslinked to suppress the movement, within the pressure-sensitive adhesive layer, of the release agent having moved to the pressure-sensitive adhesive layer, and thus the release agent is suppressed from bleeding out on the surface of the adhesive face, and the change over time of the wettability of the adhesive face can be probably thus suppressed. It is noted that this is only assumption, and hence should not be understood to limit the present invention. Such a crosslinking agent is not particularly limited, and a siloxane-based crosslinking agent (a silicone-based crosslinking agent), and a peroxide-based crosslinking agent can be favorably used. In particular, a siloxane-based crosslinking agent is preferable. The crosslinking agents can be used singly, or in a combination or two or more thereof.

For example, a polyorganohydrogensiloxane having two or more hydrogen atoms bonded to silicon atoms in the molecule can be suitably used as the siloxane-based crosslinking agent. In such a polyorganohydrogensiloxane, various organic groups other than hydrogen atoms may be bonded to silicon atoms to which hydrogen atoms are bonded. Examples of the organic group include alkyl groups such as a methyl group and an ethyl group; aryl groups such as a phenyl group; and halogenated alkyl groups, and a methyl group is preferred from the viewpoint of synthesis and handling. Further, the skeleton structure of the polyorganohydrogensiloxane may have a linear, branched, or cyclic skeleton structure, but is preferably linear.

Examples of the peroxide-based crosslinking agent to be used include diacyl peroxide, alkylperoxyester, peroxydicarbonate, monoperoxycarbonate, peroxyketal, dialkyl peroxide, hydroperoxide, and ketone peroxide. More specific examples thereof include benzoyl peroxide, t-butyl peroxybenzoate, dicumyl peroxide, t-butyl cumyl peroxide, di-t-butyl peroxide, 2,5-dimethyl-2,5-di-t-butyl peroxyhexane, 2,4-dichloro-benzoyl peroxide, di-t-butyl peroxy-diisopropylbenzene, 1,1-bis(t-butylperoxy)-3,3,5-trimethylcyclohexane, and 2,5-dimethyl-2,5-di-t-butyl peroxyhexyne-3.

As the siloxane-based crosslinking agent, for example, those under the trade name “BY24-741”, and the trade name “SE1700Catalyst” (both manufactured by Dow Toray Co., Ltd.); and the trade name “X-92-122” (manufactured by Shin-Etsu Chemical Co., Ltd.) are commercially available.

When the silicone-based pressure-sensitive adhesive composition contains a crosslinking agent, the amount of the crosslinking agent used is not particularly limited, and is preferably 0.5 parts by weight or more, more preferably 0.7 parts by weight or more, and further preferably 1 part by weight or more based on 100 parts by weight of the base polymer from the viewpoint that the low adhesiveness and the low tackiness can be controlled to suppress drop and positional deviation of an electronic component under conveyance. The upper limit of the amount used is preferably 10 parts by weight or less, and more preferably 5 parts by weight or less based on 100 parts by weight of the base polymer in that adequate flexibility is obtained in the pressure-sensitive adhesive layer to improve the adhesive strength.

The addition-type silicone-based pressure-sensitive adhesive composition preferably contains a curing catalyst such as a platinum catalyst. As the platinum catalyst, for example, those under the trade names “CAT-PL-50T” (manufactured by Shin-Etsu Chemical Co., Ltd.), and “DOWSIL NC-25 Catalyst” and “DOWSIL SRX212 Catalyst” (both manufactured by Dow Toray Co., Ltd.) are commercially available. From the viewpoint of balance of the pressure-sensitive adhesive layer's ability to receive the electronic component, positional accuracy, transferability to the mounting substrate, tack force, and the like, the content of curing catalyst is preferably about 0.1 to 10 parts by weight based on 100 parts by weight of silicone-based polymer (including silicone rubber, silicone resin, and the like) as base polymer.

The pressure-sensitive adhesive composition of the present invention may further contain, if necessary, additives such as a tackifying resin (such as a rosin derivative, a polyterpene resin, a petroleum resin, or an oil-soluble phenol), an age resistor, a filler, a colorant (such as a pigment, or a dye), an ultraviolet absorber, an antioxidant, a chain transfer agent, a plasticizer, a softener, a surfactant, and an antistatic agent as long as the effects of the present invention are not impaired. Such additives can be used singly, or in a combination or two or more thereof.

A method for producing the pressure-sensitive adhesive layer (particularly, the acrylic pressure-sensitive adhesive layer) of the present invention is not particularly limited, and examples thereof include applying (coating) the pressure-sensitive adhesive composition onto a base material or a release liner, and curing by drying the thus obtained pressure-sensitive adhesive composition layer; and applying (coating) the pressure-sensitive adhesive composition onto a base material or a release liner, and curing by irradiating the thus obtained pressure-sensitive adhesive composition layer with an active energy ray. The resultant may be dried by heating if necessary.

Examples of the active energy ray include ionizing radiation such as an α ray, a β ray, a γ ray, a neutron ray, and an electron ray, and an ultraviolet ray, and an ultraviolet ray is particularly preferable. Besides, irradiation energy, irradiation time, and irradiation method of the active energy ray are not particularly limited.

The pressure-sensitive adhesive composition can be produced by a known or commonly used method. For example, a solvent type acrylic pressure-sensitive adhesive composition can be produced by mixing a solution containing the acrylic polymer with an additive (such as an ultraviolet absorber) if necessary. For example, an active energy ray curing type acrylic pressure-sensitive adhesive composition can be produced by mixing a mixture or a partial polymer of the acrylic monomer with an additive (such as an ultraviolet absorber) if necessary.

In applying (coating) the pressure-sensitive adhesive composition, a known coating method may be employed. For example, a coater such as a gravure roll coater, a reverse roll coater, a kiss roll coater, a dip roll coater, a bar coater, a knife coater, a spray coater, a comma coater, or a direct coater may be used.

In particular, when the pressure-sensitive adhesive layer is formed from the active energy ray curing type pressure-sensitive adhesive composition, the active energy ray curing type pressure-sensitive adhesive composition preferably contains a photopolymerization initiator. When the active energy ray curing type pressure-sensitive adhesive composition contains an ultraviolet absorber, at least a photopolymerization initiator having a light absorption property in a wide wavelength range is contained as the photopolymerization initiator. For example, at least a photopolymerization initiator having a light absorption property against not only ultraviolet light but also visible light is preferably contained. This is because the curing by the active energy ray might be inhibited by the action of the ultraviolet absorber, and hence, when a photopolymerization initiator having a light absorption property in a wide wavelength range is contained, high photocurability can be easily obtained in the pressure-sensitive adhesive composition.

### (Release Liner)

The adhesive face of the pressure-sensitive adhesive layer of the present invention and/or the second pressure-sensitive adhesive layer is protected by a release liner until use. When the pressure-sensitive adhesive layer of the present invention is included in a double-coated pressure-sensitive adhesive sheet, the respective adhesive faces may be protected respectively by two release liners, or may be protected in such a manner as to be wound up into a roll by one release liner having release surfaces on both surfaces (wound form). The release liner is used as a protective material for the shock absorbing property and the adhesiveness of the pressure-sensitive adhesive layer, and is separated in use. Besides, when the pressure-sensitive adhesive layer of the present invention is included in a base material-less pressure-sensitive adhesive sheet, the release liner also plays a role as a support of the pressure-sensitive adhesive layer.

As the release liner, commonly used release paper or the like can be used, and although not particularly limited, an example includes a base material having a release layer. Examples of the base material having a release layer include plastic films and paper surface-treated with a silicone-based, long chain alkyl-based, or fluorine-based release agent.

Examples of the silicone-based release agent includes known silicone-based release agents of addition reaction type, condensation reaction type, cationic polymerization type, and radical polymerization type. Examples of products commercially available as the addition reaction type silicone-based release agent include KS-776A, KS-847T, KS-779H, KS-837, KS-778, and KS-830 (manufactured by Shin-Etsu Chemical Co., Ltd.), and SRX-211, SRX-345, SRX-357, SD7333, SD7220, SD7223, LTC-300B, LTC-350G, and LTC-310 (manufactured by Dow Toray Co., Ltd.). Examples of products commercially available as the condensation reaction type include SRX-290, and SYLOFF-23 (manufactured by Dow Toray Co., Ltd.). Examples of products commercially available as the cationic polymerization type include TPR-6501, TPR-6500, UV9300, VU9315, and UV9430 (manufactured by Momentive Performance Materials), and X62-7622 (manufactured by Shin-Etsu Chemical Co., Ltd.). An example of a product commercially available as the radical polymerization type includes X62-7205 (manufactured by Shin-Etsu Chemical Co., Ltd.). For adjusting the release performance, a silicone resin (silicon resin consisting of an R₃SiO_{1/2} unit and an SiO_{4/2} unit), silica, ethylcellulose or the like may be added to such a release agent.

Examples of the long chain alkyl-based release agent include known long chain alkyl-based release agents such as a long chain alkyl group-containing amino-alkyd resin, a long chain alkyl group-containing acrylic resin, and a long chain aliphatic pendant resin (reaction product of at least one active hydrogen-containing polymer, selected from the compound group consisting of polyvinyl alcohol, an ethylene/vinyl alcohol copolymer, a polyethylene imine, and a hydroxyl group-containing cellulose derivative, and a long chain alkyl group-containing isocyanate). It may be a release agent for performing a curing reaction with a curing agent and an ultraviolet initiator added, or may be a release agent for volatilizing a solvent for solidification.

The “long chain alkyl group” is preferably an alkyl group having 8 to 30 carbon atoms, and the number of carbon atoms may be 10 or more, 12 or more, 18 or less, 24 or less, or the like, and in particular, a linear alkyl group is preferable. Specific examples include one, two or more alkyl groups selected from a decyl group, an undecyl group, a lauryl group, a dodecyl group, a tridecyl group, a myristyl group, a tetradecyl group, a pentadecyl group, a cetyl group, a palmityl group, a hexadecyl group, a heptadecyl group, a stearyl group, an octadecyl group, a nonadecyl group, an icosyl group, and a docosyl group.

Examples of a product commercially available as the long chain alkyl-based release agent include Ashio Resin® RA-30 manufactured by Ashio-Sangyo Co., Ltd., Peeloil® 1010, Peeloil 1010S, Peeloil 1050, and Peeloil HT manufactured by Ipposha Oil Industries Co., Ltd., Resem N-137 manufactured by Chukyo Yushi Co., Ltd., Exceparl® PS-MA manufactured by Kao Corporation, and Tesfine® 303 manufactured by Hitachi Chemical Company, Ltd.

An example of the fluorine-based release agent includes a coating agent obtained by dispersing, in a binder resin, a perfluoroalkyl group-containing vinyl ether polymer, or a fluorine resin such as tetrafluoroethylene or trifluoroethylene.

The release agent may contain an antistatic agent, a silane coupling agent, a lubricant or the like if necessary.

A known method may be employed for forming a release agent layer on the surface of a plastic film or paper. Specifically, any of known coating methods such as gravure coating, Mayer bar coating, and air knife coating can be employed.

The thickness of the release liner is not particularly limited, and may be appropriately selected from a range of 5 to 100 μm.

The release strength of the release liner from the adhesive face of the pressure-sensitive adhesive layer of the present invention is preferably 0.15 N/50 mm or more. The wettability of the adhesive face changes over time when exposed to an atmospheric environment after separating the release liner probably because the release agent contained in the release layer formed on the surface of the release liner moves to the pressure-sensitive adhesive layer, and the release agent thus having moved to the pressure-sensitive adhesive layer bleeds out on the surface of the adhesive face. The release strength of the release liner is generally controlled in accordance with the amount of the release agent moving to the pressure-sensitive adhesive layer. Specifically, it is presumed that when the amount of the release agent moving to the pressure-sensitive adhesive layer is large, the adhesive strength in the vicinity of the adhesive face is reduced to reduce the release strength, and when the amount of the release agent moving to the pressure-sensitive adhesive layer is small, the adhesive strength is increased. Accordingly, when the release strength of the release liner from the adhesive face of the pressure-sensitive adhesive layer of the present invention is increased, the amount of the release agent moving to the pressure-sensitive adhesive layer is reduced, and the release agent is suppressed from bleeding out on the surface of the adhesive face, and thus, the change over time of the wettability of the adhesive face can be probably suppressed. It is noted that this is only assumption, and hence should not be understood to limit the present invention.

The configuration in which the release strength of the release liner from the adhesive face is 0.15 N/50 mm or more is favorable in that the wettability of the adhesive face is difficult to change over time even in the state where the displacement R is adjusted to 5° or less and the adhesive face is exposed to an atmospheric environment after separating the release liner, and thus, positional deviation or drop can be prevented in conveying an electronic component. The release strength of the release liner is more preferably 0.2 N/50 mm or more, and further preferably 0.25 N/50 mm or more in that the positional deviation or drop can be prevented in conveying an electronic component.

On the other hand, the release strength of the release liner from the adhesive face is preferably 5 N/50 mm or less. If the release strength of the release liner is too high, when the release liner is to be separated after fixing, on a carrier substrate or the like, the face of the pressure-sensitive adhesive sheet of the present invention opposite to the pressure-sensitive adhesive layer, separation may be caused on the interface with the carrier substrate, and hence it may be difficult to fix it on a carrier substrate or the like. Besides, when the release strength of the release liner is too high, the pressure-sensitive adhesive layer may be damaged. The configuration in which the release strength of the release liner from the adhesive face is 5 N/50 mm or less is preferable in that the pressure-sensitive adhesive sheet of the present invention is easily fixed on a carrier substrate or the like, and that the pressure-sensitive adhesive layer is prevented from being damaged. The release strength of the release liner from the adhesive face is more preferably 4.5 N/50 mm or less, and further preferably 4 N/50 mm or less in that the pressure-sensitive adhesive sheet of the present invention is easily fixed on a carrier substrate or the like, and that the pressure-sensitive adhesive layer is prevented from being damaged.

The release strength of the release liner from the adhesive face is specifically measured by a method described in Examples below, and can be adjusted by adjusting the type and amount applied of the release agent, curing conditions, the type and composition (monomer composition) of the pressure-sensitive adhesive composition contained in the pressure-sensitive adhesive layer of the present invention, and the type and amount of the crosslinking agent.

### (Second Pressure-Sensitive Adhesive Layer)

The pressure-sensitive adhesive sheet of the present invention may have a second pressure-sensitive adhesive layer stacked on the surface opposite to the adhesive face of the pressure-sensitive adhesive layer of the present invention. In other words, the pressure-sensitive adhesive sheet of the present invention may be a base material-less double-coated pressure-sensitive adhesive sheet including a pressure-sensitive adhesive layer having a double layer structure. When the pressure-sensitive adhesive sheet of the present invention is a base material-less double-coated pressure-sensitive adhesive sheet including a pressure-sensitive adhesive layer having a double layer structure, for example, the pressure-sensitive adhesive layer of the present invention can control the shock absorbing property together with the second pressure-sensitive adhesive layer. The second pressure-sensitive adhesive layer can be fixed on another substrate (carrier substrate), which is preferable from the viewpoint of workability.

The second pressure-sensitive adhesive layer may be formed from the same pressure-sensitive adhesive as the pressure-sensitive adhesive layer of the present invention, or may be formed from a different pressure-sensitive adhesive from the pressure-sensitive adhesive layer of the present invention. For example, it is preferably an adhesive strength reducible pressure-sensitive adhesive layer of a radiation-curable pressure-sensitive adhesive or a heat-expandable pressure-sensitive adhesive. This configuration is preferred from the viewpoint that an electronic component can be transferred with high adhesion between the second pressure-sensitive adhesive layer and a carrier substrate, that the second pressure-sensitive adhesive layer can be easily separated from the carrier substrate by reducing the adhesive strength of the second pressure-sensitive adhesive layer by irradiation with radiation or heating, and hence the carrier substrate can be easily reused, and reworkability is excellent.

The thickness of the second pressure-sensitive adhesive layer is not particularly limited, and is preferably 1 μm or more, and more preferably 3 μm or more. The thickness is preferably a certain value or more because thus the shock absorbing property can be easily controlled, and it can be stably fixed on a carrier substrate. The upper limit of the thickness of the second pressure-sensitive adhesive layer is not particularly limited, and is preferably 450 μm or less, and more preferably 300 μm or less. The thickness is preferably a certain value or less because thus it is easily separated from the carrier substrate, and the reworkability is improved.

### (Base Material)

The pressure-sensitive adhesive sheet of the present invention may be a pressure-sensitive adhesive sheet including a base material layer stacked on a surface opposite to the adhesive face of the pressure-sensitive adhesive layer of the present invention (including one having a double layer structure with a second pressure-sensitive adhesive layer). In other words, the pressure-sensitive adhesive sheet of the present invention may be a base material-attached pressure-sensitive adhesive sheet. The pressure-sensitive adhesive sheet of the present invention is preferably a base material-attached pressure sensitive adhesive sheet in that the base material functions as a support to improve stability and handleability in receiving an electronic component.

The base material is not particularly limited, and for example, a plastic film can be favorably used. A constituting material of a plastic base material is preferably a thermoplastic resin from the viewpoint of stability and handleability in receiving an electronic component. Examples of the thermoplastic resin include polyolefin, polyester, polyurethane, polycarbonate, polyether ether ketone, polyimide, polyether imide, polyamide, wholly aromatic polyamide, polyvinyl chloride, polyvinylidene chloride, polyphenyl sulfide, aramid, a fluororesin, a cellulose-based resin, and a silicone resin, and a polyester film is preferable. Examples of polyolefin include a low density polyethylene, a linear low density polyethylene, an intermediate density polyethylene, a high density polyethylene, an ultralow density polyethylene, a random copolymerized polypropylene, a block copolymerized polypropylene, homopolyprolene, polybutene, polymethylpentene, an ethylene-vinyl acetate copolymer, an ionomer resin, an ethylene-(meth)acrylic acid copolymer, an ethylene-(meth)acrylate copolymer, an ethylene-butene copolymer, and an ethylene-hexene copolymer. Examples of polyester include polyethylene terephthalate, polyethylene naphthalate, and polybutylene terephthalate. The base material is preferably formed from a polyester film from the viewpoint of stability and handleability in receiving an electronic component. The base material may be composed of one material, or may be composed of two or more materials. The base material may have a single layer structure, or may have a multilayer structure. Besides, when the base material is formed from a plastic film, the film may be an unstretched film, a uniaxially stretched film, or a biaxially stretched film. The release liner separated in use is not encompassed in the “base material”.

The thickness of the base material is not particularly limited, and for example, from the viewpoint of securing strength for functioning as a support, is preferably 10 μm or more, and more preferably 30 μm or more. From the viewpoint of realizing appropriate flexibility, the thickness of the base material is preferably 200 μm or less, and more preferably 180 μm or less. The base material may be in either form of a single layer and a multilayer. The surface of the base material may be appropriately subjected to a known or commonly used surface treatment, such as a physical treatment of a corona discharge treatment or a plasma treatment, or a chemical treatment of an undercoating treatment, for enhancing adhesion to the pressure-sensitive adhesive layer of the present invention.

When the pressure-sensitive adhesive layer of the present invention (including one having a double layer structure with a second pressure-sensitive adhesive layer) is included in a base material-attached pressure-sensitive adhesive sheet, a second pressure-sensitive adhesive layer may be stacked on a surface of the base material layer on which the pressure-sensitive adhesive layer is not stacked. In other words, the pressure-sensitive adhesive sheet of the present invention may be a base material-attached double-coated pressure sensitive adhesive sheet including the pressure-sensitive adhesive layer of the present invention (including one having a double structure with a second pressure-sensitive adhesive layer). The pressure-sensitive adhesive sheet of the present invention is preferably a base material-attached double-coated pressure-sensitive adhesive sheet because thus, the base material functions as a support to improve stability and handleability in receiving an electronic component, and in addition, from the viewpoint of workability because the second pressure-sensitive adhesive layer can be fixed on another substrate (carrier substrate).

### (Method for Producing Pressure-Sensitive Adhesive Sheet of Invention)

The method for producing the pressure-sensitive adhesive sheet of the present invention varies depending on the composition of the pressure-sensitive adhesive composition of the present invention and is not particularly limited, and known forming method can be used, including the following methods (1) to (4), for example.
(1) A method for producing a pressure-sensitive adhesive sheet, including applying (coating) the pressure-sensitive adhesive composition onto a base material to form a composition layer, and curing the composition layer (for example, curing by thermal curing or irradiation with active energy rays such as ultraviolet rays) to form a pressure-sensitive adhesive layer.
(2) A method for producing a pressure-sensitive adhesive sheet, including applying (coating) the pressure-sensitive adhesive composition onto a release liner to form a composition layer, curing the composition layer (for example, curing by thermal curing or irradiation with active energy rays such as ultraviolet rays) to form a pressure-sensitive adhesive layer, and then transferring the pressure-sensitive adhesive layer onto a base material.
(3) A method for producing a pressure-sensitive adhesive sheet, including applying (coating) the pressure-sensitive adhesive composition onto a base material and drying the composition to form a pressure-sensitive adhesive layer.
(4) A method for producing a pressure-sensitive adhesive sheet, including applying (coating) the pressure-sensitive adhesive composition onto a release liner, drying the composition to form a pressure-sensitive adhesive layer, and then transferring the pressure-sensitive adhesive layer onto a base material.

As a film formation method employed in (1) to (4) described above, a method in which the pressure-sensitive adhesive layer is formed by drying is preferable in excellent productivity.

As the method of applying (coating) the pressure-sensitive adhesive composition onto a predetermined surface, a known coating method can be employed and is not particularly limited, and examples thereof include roll coating, kiss roll coating, gravure coating, reverse coating, roll brushing, spray coating, dip roll coating, bar coating, knife coating, air knife coating, curtain coating, lip coating, and extrusion coating with a die coater or the like.

The thickness (total thickness) of the pressure-sensitive adhesive sheet of the present invention is not particularly limited, but is preferably 1 μm or more, more preferably 2 pam or more, and still more preferably 3 pam or more. The thickness is preferably a certain value or more because thus an electronic component can be easily transferred with accuracy to the pressure-sensitive adhesive layer of the present invention. Further, the upper limit value of the thickness (total thickness) of the pressure-sensitive adhesive sheet of the present invention is not particularly limited, but is preferably 500 pam or less, more preferably 300 pam or less. When the thickness is a certain value or less, the electronic component can be easily transferred to another carrier substrate or mounting substrate with high accuracy, which is preferable. The thickness of the pressure-sensitive adhesive sheet of the present invention does not include the thickness of the release liner.

The pressure-sensitive adhesive sheet of the present invention includes the pressure-sensitive adhesive layer of the present invention, and hence exhibits an excellent shock absorbing property. For example, a shock absorption rate (%) thereof obtained in the iron ball drop test is 10% or more, preferably 15% or more, and may be 20% or more, 25% or more, 30% or more, 35% or more, or 40% or more.

The shock absorption rate (%) is obtained in accordance with the following equation with an impact load F in applying impact under the above-described conditions measured with the iron drop test apparatus:

Shock absorption rate (%)={(S₀−S₁)/S₀×100

(In the equation, S₀ refers to an impact load obtained by colliding an iron ball to a SUS plate alone without laminating the pressure-sensitive adhesive sheet thereon, and S₁ refers to an impact load obtained by colliding an iron ball to a pressure-sensitive adhesive sheet of a structure including a SUS plate and the pressure-sensitive adhesive sheet.)

### (Processing Method for Electronic Component)

The pressure-sensitive adhesive sheet of the present invention is used in a processing method for an electronic component (processing application for an electronic component). More specifically, the pressure-sensitive adhesive sheet of the present invention is preferably used for receiving, with the pressure-sensitive adhesive layer of the present invention, an electronic component disposed on a temporary fixing material (a substrate, or a pressure-sensitive adhesive sheet). Since the pressure-sensitive adhesive sheet of the present invention comprises the pressure-sensitive adhesive layer of the present invention, impact caused by collision of an electronic component or the like to the pressure-sensitive adhesive layer can be sufficiently absorbed, and positional deviation and turning-over otherwise caused by bounce of the electronic component at the time of collision can be suppressed. Since the pressure-sensitive adhesive sheet of the present invention comprises the pressure-sensitive adhesive layer of the present invention, drop and positional deviation of an electronic component can be suppressed at the time of conveyance of the received electronic component.

The pressure-sensitive adhesive sheet of the present invention is preferably fixed on a carrier substrate with the surface opposite to the adhesive face when subjected to the processing method for an electronic component of the present invention. When the pressure-sensitive adhesive sheet of the present invention is fixed on the carrier substrate, an electronic component can be stably transferred and conveyed. As the carrier substrate, a glass plate or a plastic film described above can be used, and a glass plate is preferable from the viewpoint of stability.

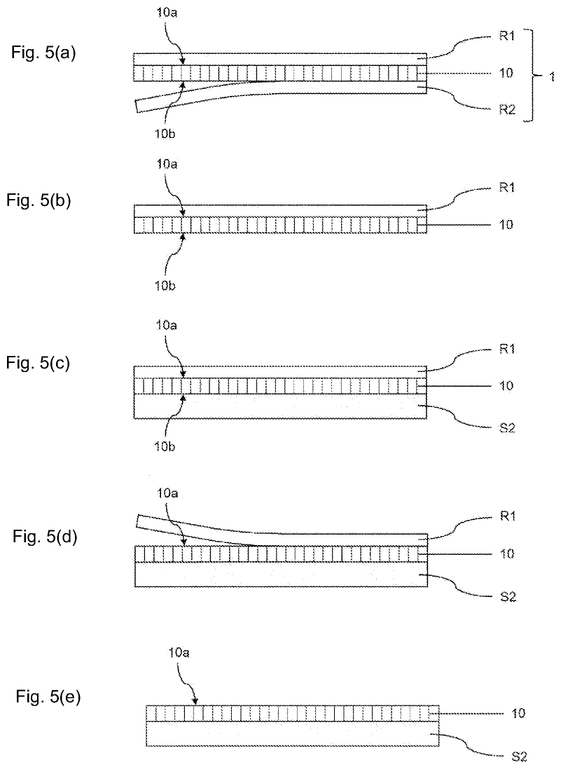

An embodiment of a method for fixing the pressure-sensitive adhesive sheet of the present invention on a carrier substrate will now be described with reference to the accompanying drawings, and it is noted that the method for fixing the pressure-sensitive adhesive sheet of the present invention on a carrier substrate is not limited to this embodiment. FIG. 5 is a schematic cross-sectional view showing one embodiment of the method for fixing the pressure-sensitive adhesive sheet of the present invention on a carrier substrate using the pressure-sensitive adhesive sheet 1 of FIG. 1.

In the method for fixing the pressure-sensitive adhesive sheet of the present invention on a carrier substrate of this embodiment, the release liner R2 of the pressure-sensitive adhesive sheet 1 is separated to expose the adhesive face 10b (see FIGS. 5(a) and 5(b)), a carrier substrate S2 is laminated onto the thus exposed adhesive face 10b (see FIG. 5(c)), and subsequently, the release liner R1 of the pressure-sensitive adhesive sheet 1 is separated to expose the adhesive face 10a (see FIGS. 5(d) and 5(e)).

In FIG. 5(a), the release liner R2 is separated from the pressure-sensitive adhesive layer 10 of the pressure-sensitive adhesive sheet 1 having been adsorbed onto a vacuum chuck stage (not shown) to expose the adhesive face 10b of the pressure-sensitive adhesive layer 10. The release strength of the release liner R2 from the adhesive face 10b is controlled to be smaller than the release strength of the release liner R1 from the adhesive face 10a from the viewpoint of preventing what is called “naki-wakare” (unwanted separation). Here, the term “naki-wakare” refers to a phenomenon in which the release liner R1 is also separated in separating the release liner R2 in the present embodiment. The release strength of the release liner R2 from the adhesive face 10b is not particularly limited as long as it is smaller than the release strength of the release liner R1 from the adhesive face 10a, and may be set to about ⅓ to ½ of the release strength of the release liner R1 from the adhesive face 10a from the viewpoint of efficiently preventing “naki-wakare”. FIG. 5(b) shows a state where the release liner R2 is completely separated to entirely expose the adhesive face 10b. Subsequently, in FIG. 5(c), the carrier substrate S2 is laminated onto the exposed adhesive face 10b.

In FIG. 5(d), the release liner R1 is separated from the pressure-sensitive adhesive layer 10 to expose the adhesive face 10a. On the surface of the release liner R1 contacting the adhesive face 10a, a release layer of a release agent of silicone-based, long chain alkyl-based, fluorine-based or the like is formed (not shown). A part of the release agent contained in the release layer has moved to the pressure-sensitive adhesive layer 10. In the present embodiment, the amount of the release agent moving to the pressure-sensitive adhesive layer 10 is suppressed by controlling the release strength of the release liner R1 from the adhesive face 10a. FIG. 5(e) shows a state where the release liner R1 is completely separated to entirely expose the adhesive face 10a, and in this state, the pressure-sensitive adhesive sheet is subjected to the processing method for an electronic component of the present invention.

When the pressure-sensitive adhesive sheet of the present invention is used in the processing application for an electronic component, a surface of the temporary fixing material on which an electronic component is disposed and the adhesive face of the pressure-sensitive adhesive layer of the pressure-sensitive adhesive sheet of the present invention are preferably disposed so as to face each other with a gap provided therebetween. This configuration is preferable in that the positional relationship between the temporary fixing material and the pressure-sensitive adhesive sheet of the present invention can be controlled, and that the electronic component can be disposed in a desired position on the pressure-sensitive adhesive sheet.

The processing method for an electronic component of the present invention includes a step of receiving an electronic component disposed on a temporary fixing material with the adhesive face of the pressure-sensitive adhesive layer of the pressure-sensitive adhesive sheet of the present invention (first step). In the processing method for an electronic component of the present invention, the pressure-sensitive adhesive sheet of the present invention can sufficiently absorb impact caused by collision of an electronic component or the like to the pressure-sensitive adhesive layer, and positional deviation and turning-over otherwise caused by bounce of the electronic component at the time of collision can be suppressed.

In the processing method for an electronic component of the present invention, the surface of the temporary fixing material on which an electronic component is disposed and the adhesive face of the pressure-sensitive adhesive layer of the pressure-sensitive adhesive sheet of the present invention are preferably disposed so as to face each other with a gap provided therebetween. This configuration is preferable in that the positional relationship between the temporary fixing material and the pressure-sensitive adhesive sheet of the present invention can be controlled, and that the electronic component can be disposed in a desired position on the pressure-sensitive adhesive sheet.

The processing method for an electronic component of the present invention preferably further includes a step of disposing the electronic component on the pressure-sensitive adhesive sheet on another pressure-sensitive adhesive sheet or another substrate (second step), and a step of separating the electronic component from the adhesive face of the pressure-sensitive adhesive layer of the pressure-sensitive adhesive sheet (third step). When the processing method for an electronic component of the present invention includes the second step and the third step, the electronic component can be efficiently transferred.

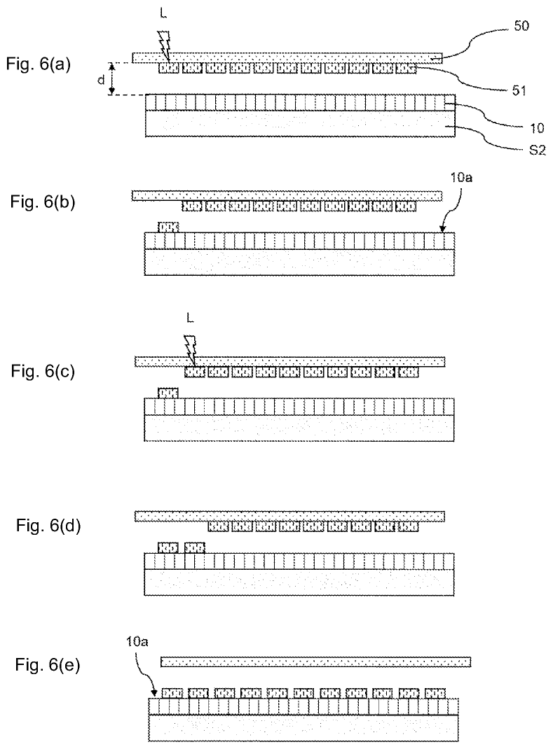

An embodiment of the processing method for an electronic component of the present invention will now be described with reference to the accompanying drawings, and it is noted that the processing method for an electronic component of the present invention is not limited to this embodiment. FIG. 6 is a schematic cross-sectional view showing a first step of the processing method for an electronic component of the present invention using the pressure-sensitive adhesive sheet fixed on the carrier substrate shown in FIG. 5 (see FIG. 5(e)).

In the present embodiment, the first step of the processing method for an electronic component of the present invention is a step in which an electronic component 51 disposed on a temporary fixing material 50 (see FIG. 6(a)) is dissociated, and received with the adhesive face 10a of the pressure-sensitive adhesive layer 10 fixed on the carrier substrate S2 (see FIGS. 6(b) and 6(c)).

In FIG. 6(a), a plurality of electronic components 51 are disposed on one surface of the temporary fixing material 50. A material constituting the temporary fixing material 50 is not particularly limited, and examples thereof include a plastic film and a glass substrate described above. The temporary fixing material 50 may be a pressure-sensitive adhesive sheet, and in this case, the electronic components 51 may be disposed on an adhesive face of the pressure-sensitive adhesive sheet. The temporary fixing material 50 is preferably formed from a radiation transparent material.

A method for disposing the electronic components 51 on one surface of the temporary fixing material 50 is not particularly limited, and for example, the electronic components 51 are disposed via an adhesive strength reducible pressure-sensitive adhesive layer described above. In this case, temporary fixation can be released by irradiating with radiation or heating the adhesive strength reducible pressure-sensitive adhesive layer. In the present embodiment, the electronic components 51 are disposed on the temporary fixing material 50 via a radiation-curable pressure-sensitive adhesive layer described above (not shown).

In the present embodiment, a plurality of electronic components 51 are disposed on one surface of the temporary fixing material 50. In the present embodiment, the size of each electronic component 51 is, for example, 1 μm² to 250000 μm². According to the processing method for an electronic component of the present invention, such compact electronic components can be efficiently transferred.

In the present embodiment, the temporary fixing material 50 is disposed to have the surface having the electronic components 51 disposed thereon to face downward, the pressure-sensitive adhesive layer 10 fixed on the carrier substrate S2 is disposed to have the adhesive face 10a to face upward, and the surface of the temporary fixing material 50 on which the electronic components 51 are temporarily fixed and the adhesive face 10a of the pressure-sensitive adhesive layer 10 are disposed so as to face each other with a gap d provided therebetween. Since the gap d is provided, the positional relationship between the temporary fixing material 50 and the pressure-sensitive adhesive layer 10 can be controlled, and the electronic components 51 can be disposed in desired positions on the pressure-sensitive adhesive layer 10. The dimension of the gap d is not particularly limited, and is, for example, about 1 to 1000 μm.

In the present embodiment, the temporary fixation of the electronic components 51 is released by irradiating the electronic components 51 with a laser beam L from the side of the temporary fixing material 50, and thus, the electronic components 51 are dissociated from the temporary fixing material 50. In more detail, when portions of the temporary fixing material 50 contacting the electronic components 51 are irradiated with the laser beam L, the adhesive strength is reduced, and thus, the electronic components 51 are dissociated by separating from the temporary fixing material 50. The laser beam L may irradiate the plurality of electronic components 51 individually, may irradiate some thereof, may irradiate all the electronic components 51 collectively, or may irradiate by sweeping. In the present embodiment, some of the plurality of electronic components 51 are irradiated.

In FIG. 6(b), the electronic components 51 dissociated from the temporary fixing material 50 drop toward the pressure-sensitive adhesive layer 10, and are received on the adhesive face 10a. The pressure-sensitive adhesive layer 10 includes the pressure-sensitive adhesive layer of the present invention, and hence exhibits an excellent shock absorbing property, impact caused by collision of the electronic components is absorbed, and thus, damage can be prevented, and positional deviation and turning-over of the electronic components can be suppressed.

In FIGS. 6(c) and 6(d), another electronic component 51 disposed on the temporary fixing material 50 is dissociated and dropped by irradiation with the laser beam L so as to be received on (transferred to) the adhesive face 10a of the pressure-sensitive adhesive layer 10. In the present embodiment, an electronic component 51 adjacent to the electronic component 51 irradiated with the laser beam L in FIG. 6(a) is irradiated with the laser beam L.

In FIGS. 6(c) and 6(d), the positional relationship between the temporary fixing material 50 and the pressure-sensitive adhesive layer 10 may be the same as that in FIG. 6 (b), or the positional relationship may be shifted. In the present embodiment, the laser beam L is irradiated after shifting the temporary fixing material 50 rightward in FIG. 6 against the pressure-sensitive adhesive layer 10 by a certain distance. Thus, the electronic component 51 can be disposed on the pressure-sensitive adhesive layer 10 with a pitch controlled to a desired pitch.

FIG. 6(e) shows a form in which the steps shown in FIGS. 6(c) and 6(d) are repeated so as to receive all the electronic components 51 on the pressure-sensitive adhesive layer 10. In the present embodiment, the electronic components 51 are arranged at a desired pitch provided therebetween.

During the steps of FIGS. 6(a) to 6(d), and during storage in the state of FIG. 6(e), the adhesive face 10a of the pressure-sensitive adhesive layer 10 is exposed to an atmospheric environment. It is presumed that when the adhesive face 10a is exposed to an atmospheric environment, the release agent having moved to the pressure-sensitive adhesive layer 10 from the release layer formed on the surface of the release liner R1 contacting the adhesive face 10a bleeds out on the adhesive face 10a. When the release agent bleeds out on the adhesive face 10a, the wettability and adhesiveness of the adhesive face 10a reduce over time, ability of holding an electronic component 51 is reduced, and hence, a failure such as drop or positional deviation of the electronic component 51 can occur when the electronic component 51 held on the pressure-sensitive adhesive layer 10 is conveyed or subjected to the next step.

In the present embodiment, since the amount of the release agent moving to the pressure-sensitive adhesive layer 10 is suppressed, the reduction over time of the wettability and adhesiveness of the adhesive face 10a under an atmospheric environment is suppressed, and hence, the failure such as drop or positional deviation of the electronic component 51 can be suppressed when the electronic component 51 held on the pressure-sensitive adhesive layer 10 is conveyed or subjected to the next step.

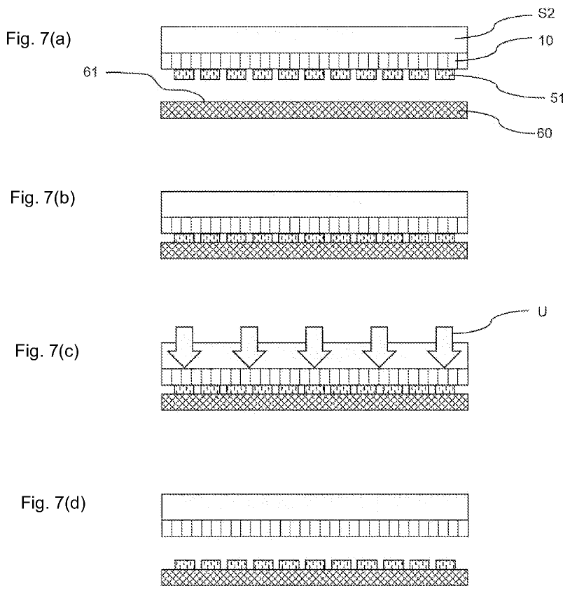

FIG. 7 is a schematic cross-sectional view showing a second step and a third step in one embodiment of the processing method for an electronic component of the present invention using the pressure-sensitive adhesive sheet fixed on the carrier substrate shown in FIG. 5.

As shown in FIG. 7(a), the electronic components 51 arranged on the adhesive face 10a of the pressure-sensitive adhesive layer 10 fixed on the carrier substrate S2 are disposed so as to face a different pressure-sensitive adhesive sheet or substrate 60 and to be spaced apart from each other. When the substrate 60 is a pressure-sensitive adhesive sheet, a surface 61 of the substrate 60 facing the pressure-sensitive adhesive layer 10 is an adhesive face, and when the substrate 60 is a mounting substrate, the surface 61 is a circuit surface.

In FIG. 7(a), the electronic components 51 in the state of FIG. 6(e) are inverted and disposed downward so as to face the surface 61 of the substrate 60. Since the amount of the release agent moving to the pressure-sensitive adhesive layer 10 is suppressed to suppress the reduction over time of the wettability and adhesiveness of the adhesive face 10a under an atmospheric environment, even when the electronic components 51 are conveyed in the form of FIG. 7(a) to be disposed downward, the electronic components 51 on the adhesive face 10a of the pressure-sensitive adhesive layer 10 are kept to be held without dropping or positionally deviating.

Next, as shown in FIG. 7(b), the surface 61 of the different pressure-sensitive adhesive sheet or substrate 60 and the electronic components 51 arranged on the adhesive face 10a of the pressure-sensitive adhesive layer 10 are brought close to each other to contact the electronic components 51 and the surface 61 each other, and thus, the electronic components 51 can be disposed on the surface 61 of the different pressure-sensitive adhesive sheet or substrate 60.

Next, when the pressure-sensitive adhesive layer 10 is formed from a radiation-curable pressure-sensitive adhesive, the electronic components 51 are irradiated with an ultraviolet ray U from the side of the carrier substrate S2 as shown in FIG. 7(c). The pressure-sensitive adhesive layer 10 formed from the radiation-curable pressure-sensitive adhesive is cured by the ultraviolet ray U, the adhesive strength is reduced, and hence the electronic components 51 become separatable. The ultraviolet ray U may irradiate all the electronic components 51, or if necessary, may irradiate some of the electronic components 51 by using a mask or the like. In the present embodiment, all the electronic components 51 are irradiated with the ultraviolet ray U.

Next, as shown in FIG. 7(d), the pressure-sensitive adhesive layer 10 is spaced apart from the different pressure-sensitive adhesive sheet or substrate 60, and thus, the electronic components 51 can be separated from the adhesive face 10a of the pressure-sensitive adhesive layer 10, and at the same time, are transferred to the surface 61 of the different pressure-sensitive adhesive sheet or substrate 60. Since the radiation-curable pressure-sensitive adhesive constituting the pressure-sensitive adhesive layer 10 has been cured to reduce the adhesive strength by the ultraviolet ray U, the electronic components 51 can be easily separated to be transferred to and disposed on the surface 61 of the different pressure-sensitive adhesive sheet or substrate 60. The electronic components 51 are transferred to and disposed on the surface 61 with a layout pattern on the pressure-sensitive adhesive layer 10 kept.

In FIGS. 5 to 7, the pressure-sensitive adhesive sheet 1 may be replaced with any of the pressure-sensitive adhesive sheets 2 to 4 shown in FIGS. 2 to 4 to similarly perform the processing method for an electronic component. In using the pressure-sensitive adhesive sheet 3, the base material S1 may be fixed on the carrier substrate S2 with a double-coated pressure-sensitive adhesive tape or the like.

Electronic components to be mounted on the mounting substrate are not particularly limited, but fine and thin semiconductor chips and LED chips can be suitably used.

### EXAMPLES

The present invention will be described in more detail below with reference to Examples, but the present invention is not limited to these Examples.

### [Production Example 1] Production of Acrylic Polymer A

To toluene, 100 parts by weight of 2-ethylhexyl acrylate, 12.6 parts by weight of 2-hydroxyethyl acrylate, and 0.25 parts by weight of benzoyl peroxide as a polymerization initiator were added, a polymerization reaction was performed in a nitrogen gas stream at 60° C., and 13.5 parts by weight of methacryloyloxyethyl isocyanate was added to the resultant to perform an addition reaction, and thus, a solution of an acrylic copolymer having a carbon-carbon double bond (acrylic polymer A) in toluene was obtained.

### Example 1

### (Preparation of Pressure-Sensitive Adhesive)

To an acrylic polymer solution A containing 100 parts by weight of the acrylic polymer A, 0.2 parts by weight of a crosslinking agent (manufactured by Nippon Polyurethane Industries Co., Ltd., trade name “Coronate L”), and 3 parts by weight of an α-hydroxyketone-based photopolymerization initiator (manufactured by BASF Japan, trade name “Irgacure 127”, molecular weight: 340.4, absorption coefficient at a wavelength of 365 nm: 1.07×10² ml/g·cm) were added to obtain a pressure-sensitive adhesive.

### (Pressure-Sensitive Adhesive Sheet)

On a release-treated surface of a release liner 1 (manufactured by Fujico Co., Ltd., trade name “PET-75-SCB5”, thickness: 75 μm), the above-described pressure-sensitive adhesive was applied so as to have a thickness after solvent volatilization (drying) of 50 μm, and thus, a pressure-sensitive adhesive layer was formed. An adhesive face of the thus obtained pressure-sensitive adhesive layer was protected by a release liner 2 (manufactured by Fujico Co., Ltd., trade name “PET-50-SCA1”, thickness: 50 μm), and thus, a pressure-sensitive adhesive sheet consisting of (the release liner 1/the pressure-sensitive adhesive layer/the release liner 2) was obtained.

### Example 2

A pressure-sensitive adhesive sheet consisting of (the release liner 1/the pressure-sensitive adhesive layer/a release liner 3) was obtained in the same manner as in Example 1 except that the release liner 3 (manufactured by Fujico Co., Ltd., trade name “PET-38-SCA1”, thickness: 38 μm) was used instead of the release liner 2.

### Example 3

A pressure-sensitive adhesive sheet consisting of (a release liner 4/the pressure-sensitive adhesive layer/the release liner 1) was obtained in the same manner as in Example 1 except that the release liner 4 (manufactured by Fujico Co., Ltd., trade name “PET-75-SC3”, thickness: 75 μm) was used instead of the release liner 1, and that the release liner 1 was used instead of the release liner 2.

### Example 4

### (Preparation of Pressure-Sensitive Adhesive)

To a silicone-based polymer solution B containing 100 parts by weight of a silicone polymer B (manufactured by Dow Toray Co., Ltd., trade name “SD4600FC”), 1.0 part by weight of a crosslinking agent (manufactured by Dow Toray Co., Ltd., trade name “BY 24-741”) and 0.9 parts by weight of a platinum catalyst (manufactured by Dow Toray Co., Ltd., trade name “SRX212Catalyst”) were added to obtain a pressure-sensitive adhesive.

### (Pressure-Sensitive Adhesive Sheet)

On a release-treated surface of a release liner 5 (manufactured by Mitsubishi Chemical Corporation, trade name “MRS #50”, thickness: 50 μm), the above-described pressure-sensitive adhesive was applied so as to have a thickness after solvent volatilization (drying) of 50 μm, and thus, a pressure-sensitive adhesive layer was formed. An adhesive face of the thus obtained pressure-sensitive adhesive layer was protected by a release liner 6 (manufactured by Fujico Co., Ltd., trade name “SK1U”, thickness: 38 μm), and thus, a pressure-sensitive adhesive sheet consisting of (the release liner 5/the pressure-sensitive adhesive layer/the release liner 6) was obtained.

### Example 5

### (Preparation of Pressure-Sensitive Adhesive)

To a silicone-based polymer solution C containing 100 parts by weight of a silicone polymer B (manufactured by Dow Toray Co., Ltd., trade name “SD4600FC”) and 30 parts by weight of a silicone polymer C (manufactured by Dow Toray Co., Ltd., trade name “SE1700”), 1.0 part by weight of a crosslinking agent (manufactured by Dow Toray Co., Ltd., trade name “BY 24-741”), 3 parts by weight of a crosslinking agent (manufactured by Dow Toray Co., Ltd., trade name “SE1700Catalyst”), and 0.9 parts by weight of a platinum catalyst (manufactured by Dow Toray Co., Ltd., trade name “SRX212Catalyst”) were added to obtain a pressure-sensitive adhesive.

### (Pressure-Sensitive Adhesive Sheet)

On a release-treated surface of a release liner 5 (manufactured by Mitsubishi Chemical Corporation, trade name “MRS #500”, thickness: 50 μm), the above-described pressure-sensitive adhesive was applied so as to have a thickness after solvent volatilization (drying) of 50 μm, and thus, a pressure-sensitive adhesive layer was formed. An adhesive face of the thus obtained pressure-sensitive adhesive layer was protected by a release liner 6 (manufactured by Fujico Co., Ltd., trade name “SK1U”, thickness: 38 μm), and thus, a pressure-sensitive adhesive sheet consisting of (the release liner 5/the pressure-sensitive adhesive layer/the release liner 6) was obtained.

### Comparative Example 1

### (Preparation of Pressure-Sensitive Adhesive)

To an acrylic polymer solution A containing 100 parts by weight of the acrylic polymer A, 0.2 parts by weight of a crosslinking agent (manufactured by Nippon Polyurethane Industries Co., Ltd., trade name “Coronate L”), and 3 parts by weight of an α-hydroxyketone-based photopolymerization initiator (manufactured by BASF Japan, trade name “Irgacure 127”, molecular weight: 340.4, absorption coefficient at a wavelength of 365 nm: 1.07×10² ml/g·cm) were added to obtain a pressure-sensitive adhesive.

### (Pressure-Sensitive Adhesive Sheet)

On a release-treated surface of a release liner 7 (manufactured by Fujico Co., Ltd., trade name “PET-75-SCA1”, thickness: 75 μm), the above-described pressure-sensitive adhesive was applied so as to have a thickness after solvent volatilization (drying) of 30 μm, and thus, a pressure-sensitive adhesive layer was formed. An adhesive face of the thus obtained pressure-sensitive adhesive layer was protected by a release liner 8 (manufactured by Toray Industries Inc., trade name “Cerapeel MDA”, thickness: 38 μm), and thus, a pressure-sensitive adhesive sheet consisting of (the release liner 7/the pressure-sensitive adhesive layer/the release liner 8) was obtained.

### Comparative Example 2

A pressure-sensitive adhesive sheet consisting of (the release liner 7/the pressure-sensitive adhesive layer/the release liner 8) was obtained in the same manner as in Comparative Example 1 except that the thickness after solvent volatilization (drying) of the pressure-sensitive adhesive layer was 50 μm.

### <Evaluation>

The pressure-sensitive adhesive sheets obtained in Examples and Comparative Examples were evaluated as follows. Results are shown in Table 1.

### (1) Contact Angle

The release liners (the release liner 2 in Example 1, the release liner 3 in Example 2, the release liner 1 in Example 3, the release liner 6 in Examples 4 and 5, and the release liner 8 in Comparative Examples 1 and 2) of the pressure-sensitive adhesive sheets obtained in Examples and Comparative Examples were separated, and each of the thus exposed surfaces of the pressure-sensitive adhesive layers was laminated onto a slide glass (manufactured by Matsunami Glass Industry Co., Ltd., 26 mm×76 mm) with a 2 kg hand roller.

Immediately after separating the release liner (the release liner 1 in Examples 1 and 2, the release liner 4 in Example 3, the release liner 5 in Examples 4 and 5, and the release liner 7 in Comparative Examples 1 and 2) from an evaluation surface of each of the evaluation samples obtained as described above, a value of a contact angle on the thus exposed surface of the pressure-sensitive adhesive layer was measured 5 seconds after dropping 2 μL of water onto the surface of the pressure-sensitive adhesive layer with a contact angle meter (manufactured by Kyowa Interface Science Co., Ltd., trade name “CX-A type”). The measurement was performed with N=5, and an average of these measured values was defined as an initial contact angle θ₁.

Besides, as for a contact angle after 2 hour exposure, the release liner (the release liner 1 in Examples 1 and 2, the release liner 4 in Example 3, the release liner 5 in Examples 4 and 5, and the release liner 7 in Comparative Examples 1 and 2) of the evaluation surface of each of the evaluation samples obtained as described above was separated, and the thus exposed surface of the pressure-sensitive adhesive layer was exposed to an atmospheric environment for 2 hours, and then, a contact angle θ₂ after 2 hour exposure was measured under the same conditions as those described above.

A displacement R (°) of the contact angle was obtained according to the following equation:

Displacement R(°)=θ₂−θ₁

### (2) Iron Ball Drop Test (Sinking Depth/Thickness)

The release liners (the release liner 2 in Example 1, the release liner 3 in Example 2, the release liner 1 in Example 3, the release liner 6 in Examples 4 and 5, and the release liner 8 in Comparative Examples 1 and 2) of the pressure-sensitive adhesive sheets (width of 30 mm×length of 30 mm) obtained in Examples and Comparative Examples were separated, and the whole surface of each of the thus exposed surfaces of the pressure-sensitive adhesive layers was laminated onto a SUS plate (thickness of 5 mm) via a double-coated pressure-sensitive adhesive tape (manufactured by Nitto Denko Corporation, trade name “No. 5600”) with a 2 kg hand roller.

The release liner (the release liner 1 in Examples 1 and 2, the release liner 4 in Example 3, the release liner 5 in Examples 4 and 5, and the release liner 7 in Comparative Examples 1 and 2) of the evaluation surface of each of the evaluation samples obtained as described above was separated, and on the thus exposed surface of the pressure-sensitive adhesive layer, an iron ball of 1 g was freely dropped from a height of 1 m with an iron ball test apparatus. A sinking depth on the pressure-sensitive adhesive layer caused by the iron ball was measured with a confocal laser microscope. Next, the sinking depth (μm) was divided by the thickness (μm) of the pressure-sensitive adhesive layer to obtain a value per unit thickness (sinking depth/thickness×100) (%).

(3) Adhesive Strength (from SUS 304)

The release liners (the release liner 2 in Example 1, the release liner 3 in Example 2, the release liner 1 in Example 3, the release liner 6 in Examples 4 and 5, and the release liner 8 in Comparative Examples 1 and 2) of the pressure-sensitive adhesive sheets (width of 30 mm×length of 30 mm) obtained in Examples and Comparative Examples were separated, and onto the whole surface of each of the thus exposed surfaces of the pressure-sensitive adhesive layers, a polyethylene terephthalate film (manufactured by Toray Industries Inc., trade name “Lumirror S10”, thickness: 50 μm) was laminated. Subsequently, the release liner (the release liner 1 in Examples 1 and 2, the release liner 4 in Example 3, the release liner 5 in Examples 4 and 5, and the release liner 7 in Comparative Examples 1 and 2) of the evaluation surface was separated, and initial adhesive strength immediately after laminating the thus exposed surface of the pressure-sensitive adhesive layer onto SUS 304 was measured by a method in accordance with JIS Z 0237:2000 (lamination condition: one reciprocation of 2 kg roller, tensile speed: 300 mm/min, peeling angle: 180°, measurement temperature: 23° C.).

The whole surface of the pressure-sensitive adhesive layer of the pressure-sensitive adhesive sheet whose evaluation surface of the pressure-sensitive adhesive layer was laminated onto SUS 304 was irradiated with an ultraviolet ray of a high pressure mercury lamp (specific wavelength: 365 nm, integrated light amount: 460 mJ/cm²) using an ultraviolet irradiation device (manufactured by Nittoseiki Co., Ltd., trade name “UM-810”), and then adhesive strength after irradiation with radiation was measured in the same manner as described above.

### (6) Release Strength

The release liners (the release liner 2 in Example 1, the release liner 3 in Example 2, the release liner 1 in Example 3, the release liner 6 in Examples 4 and 5, and the release liner 8 in Comparative Examples 1 and 2) of the pressure-sensitive adhesive sheets obtained in Examples and Comparative Examples were separated, and each of the thus exposed surfaces of the pressure-sensitive adhesive layers was laminated onto SUS 304 with a 2 kg hand roller.

Release strength of the release liner (the release liner 1 in Examples 1 and 2, the release liner 4 in Example 3, the release liner 5 in Examples 4 and 5, and the release liner 7 in Comparative Examples 1 and 2) from the evaluation surface of each of the evaluation samples obtained as described above was measured by a method in accordance with TM0001 A method (tensile speed: 300 mm/min, maximum value obtained by attaching an auxiliary plate and tearing it off by 50 mm).

### (5) Probe Tack Value

The release liners (the release liner 2 in Example 1, the release liner 3 in Example 2, the release liner 1 in Example 3, the release liner 6 in Examples 4 and 5, and the release liner 8 in Comparative Examples 1 and 2) of the pressure-sensitive adhesive sheets (width of 20 mm×length of 50 mm) obtained in Examples and Comparative Examples were separated, and the whole surface of each of the thus exposed surfaces of the pressure-sensitive adhesive layers was laminated onto a slide glass (manufactured by Matsunami Glass Industry Co., Ltd., 26 mm×76 mm) via a double-coated pressure sensitive adhesive tape (Nitto Denko Corporation, trade name “No. 5600”) with a 2 kg hand roller.

Immediately after separating the release liner (the release liner 1 in Examples 1 and 2, the release liner 4 in Example 3, the release liner 5 in Examples 4 and 5, and the release liner 7 in Comparative Examples 1 and 2) from the evaluation surface of each of the evaluation samples obtained as described above, a probe tack value of the thus exposed surface of the pressure-sensitive adhesive layer was measured with a probe tack measuring device (manufactured by RHESCA, trade name “TACKINESS Model TAC-II”) using a 5 mmΦ SUS probe under conditions of immersion speed: 120 mm/min, test speed: 600 mm/min, preload: 20 gf, and press time: 1 sec. The measurement was performed with N=5, and an average of these measured values was defined as an initial probe tack value P₀ (N/cm²).

Besides, as for a probe tack value after 2 hour exposure, after separating the release liner (the release liner 1 in Examples 1 and 2, the release liner 4 in Example 3, the release liner 5 in Examples 4 and 5, and the release liner 7 in Comparative Examples 1 and 2) from the evaluation surface of each of the evaluation samples obtained as described above, the thus exposed surface of the pressure-sensitive adhesive layer was exposed to an atmospheric environment for 2 hours, and then, a probe tack value P₁ (N/cm²) after 2 hour exposure was measured under the same conditions as those described above.

A change rate (%) of the probe tack value was obtained in accordance with the following equation:

Change rate (%) of probe tack value=(P₁−P₀)/P₀×100

Besides, conveyability of electronic components was evaluated in accordance with the following evaluation criteria:
∘ (good conveyability): The change rate of the probe tack value is more than −14%.
x (poor conveyability): The change rate of the probe tack value is −14% or less.

TABLE 1

| | | | Ex. 1 | Ex. 2 | Ex. 3 |
|---|---|---|---|---|---|
| Side of | Product | | PET-75-SCB5 | | PET-75-SC3 |
| Release | Thickness [μm] | | 75 | | 75 |
| Liner | | | | | |
| Evaluation | | | | | |
| Surface | | | | | |
| Pressure- | Polymer | Acrylic Polymer A [parts] | 100 | 100 | 100 |
| sensitive | | Silicone Polymer B [parts] | — | — | — |
| Adhesive | | Silicone Polymer C [parts] | — | — | — |
| Layer | Crosslinking Agent | Coronate L [parts | 0.2 | 0.2 | 0.2 |
| | | BY 24-741 [parts] | — | — | — |
| | | SE1700cat. [parts] | — | — | — |
| | Photopolymerization | Irg 127 [parts] | 3 | 3 | 3 |
| | Initiator | | | | |
| | Platinum Catalyst | SRX 212Cat. [parts] | — | — | — |
| | Thickness [μm] | | 50 | 50 | 50 |
| Release | Product | | PET-50-SCA1 | PET-38-SCA1 | PET-75-SCB5 |
| Liner | Thickness [μm] | | 50 | 38 | 75 |
| Pressure- | Pressure-sensitive Adhesive Layer Thickness [μm] | | 50 | 50 | 50 |
| sensitive | Contact Angle | Initial Contact Angle θ₀ | 117.20 | 116.90 | 115.40 |
| Adhesive | | Contact Angle 01 after 2 hour Exposure | 118.30 | 117.90 | 116.80 |
| Sheet | | Displacement R [°] | 1.10 | 1.00 | 1.40 |
| | Iron Ball Drop Test | Pressure-sensitive Adhesive Sinking Radius [mm] | 0.467 | 0.459 | 0.471 |
| | | Pressure-sensitive Adhesive Sinking Amount [μm] | 34.5 | 33.4 | 35.1 |
| | | Pressure-sensitive Adhesive Sinking | 69.1 | 66.7 | 70.3 |
| | | Amount/Thickness × 100 [%] | | | |
| | Adhesive Strength | Initial Adhesive Strength [N/20 mm] | 7.44 | 7.29 | 7.63 |
| | | (UV Pressure-sensitive Adhesive Side) | | | |
| | | Adhesive Strength after Irradiation with Radiation | 0.05 | 0.06 | 0.06 |
| | | [N/20 mm] | | | |
| | Release Strength | Evaluation Surface Side [N/50 mm] | 0.33 | 0.29 | 0.35 |
| | Probe Tack | Initial Probe Tack P₀ [N/cm²] | 25.20 | 24.92 | 26.24 |
| | | Probe Tack P1 after 2 hour Exposure [N/cm²] | 24.18 | 23.95 | 25.21 |
| | | Probe Tack Change Rate [%] | −4.1 | −3.9 | −3.9 |
| | | Conveyability | ∘ | ∘ | ∘ |

| | | | | | Comp. | Comp. |
|---|---|---|---|---|---|---|
| | | | Ex. 4 | Ex. 5 | Ex. 1 | Ex. 2 |
| Side of | Product | | MRS#50 | | PET-75-SCA1 | |
| Release | Thickness [μm] | | 50 | 50 | 75 | |
| Liner | | | | | | |
| Evaluation | | | | | | |
| Surface | | | | | | |
| Pressure- | Polymer | Acrylic Polymer A [parts] | — | — | 100 | 100 |
| sensitive | | Silicone Polymer B [parts] | 100 | 100 | — | — |
| Adhesive | | Silicone Polymer C [parts] | — | 30 | — | — |
| Layer | Crosslinking Agent | Coronate L [parts | — | — | 0.2 | 0.2 |
| | | BY 24-741 [parts] | 1 | 1 | — | — |
| | | SE1700cat. [parts] | — | 3 | — | — |
| | Photopolymerization | Irg 127 [parts] | — | — | 3 | 3 |
| | Initiator | | | | | |
| | Platinum Catalyst | SRX 212Cat. [parts] | 0.9 | 0.9 | — | — |
| | Thickness [μm] | | 50 | 50 | 30 | 50 |
| Release | Product | | SK1U | | Cerapeel MD | |
| Liner | Thickness [μm] | | 38 | | 38 | |
| Pressure- | Pressure-sensitive Adhesive Layer Thickness [μm] | | 50 | 50 | 30 | 50 |
| sensitive | Contact Angle | Initial Contact Angle θ₀ | 113.83 | 113.27 | 114.33 | 116.13 |
| Adhesive | | Contact Angle 01 after 2 hour Exposure | 114.27 | 111.27 | 127.30 | 121.73 |
| Sheet | | Displacement R [°] | 0.43 | −2.00 | 12.97 | 5.60 |
| | Iron Ball Drop Test | Pressure-sensitive Adhesive Sinking Radius [mm] | 0.452 | 0.428 | 0.297 | 0.461 |
| | | Pressure-sensitive Adhesive Sinking Amount [μm] | 32.3 | 29.0 | 13.9 | 33.6 |
| | | Pressure-sensitive Adhesive Sinking | 64.7 | 58.0 | 46.4 | 67.3 |
| | | Amount/Thickness × 100 [%] | | | | |
| | Adhesive Strength | Initial Adhesive Strength [N/20 mm] | 6.90 | 1.32 | 8.82 | 8.08 |
| | | (UV Pressure-sensitive Adhesive Side) | | | | |
| | | Adhesive Strength after Irradiation with Radiation | 6.80 | 1.28 | 0.06 | 0.07 |
| | | [N/20 mm] | | | | |
| | Release Strength | Evaluation Surface Side [N/50 mm] | 4.72 | 1.72 | 0.13 | 0.14 |
| | Probe Tack | Initial Probe Tack P₀ [N/cm²] | 20.63 | 11.19 | 19.60 | 21.68 |
| | | Probe Tack P1 after 2 hour Exposure [N/cm²] | 20.69 | 11.07 | 15.88 | 18.51 |
| | | Probe Tack Change Rate [%] | 0.3 | −1.0 | −19.0 | −14.6 |
| | | Conveyability | ∘ | ∘ | x | x |

Variations of the present invention described so far will be described below.

[Supplementary Note 1] A pressure-sensitive adhesive sheet comprising a pressure-sensitive adhesive layer having an adhesive face protected by a release liner,
wherein a displacement R of water contact angles θ₁ and θ₂ against the adhesive face under the following conditions T₁ and T₂ is 5° or less:
T₁: immediately after separating the release liner under an environment of 23° C.
T₂: after 2 hour exposure of the adhesive face to an atmospheric environment after separating the release liner under an environment of 23° C.
θ₁: water contact angle (°) of the adhesive face under T₁
θ₂: water contact angle (°) of the adhesive face under T₂

$$Displacement R ( ° ) = {θ}_{2} - {θ}_{1} .$$

[Supplementary Note 2] The pressure-sensitive adhesive sheet according to supplementary note 1, wherein the pressure-sensitive adhesive sheet is used for receiving an electronic component disposed on a temporary fixing material.
[Supplementary Note 3] The pressure-sensitive adhesive sheet according to supplementary note 1 or 2, wherein the pressure-sensitive adhesive sheet is to be disposed so as to face, with a gap provided therebetween, a surface of a temporary fixing material on which an electronic component is disposed, and used for receiving the electronic component.
[Supplementary Note 4] The pressure-sensitive adhesive sheet according to any one of supplementary notes 1 to 3, wherein a ratio of a sinking depth of the pressure-sensitive adhesive layer, obtained by an iron ball drop test performed on the adhesive face of the pressure-sensitive adhesive layer under the following condition, to a thickness of the pressure-sensitive adhesive layer (sinking depth/thickness×100) is 15% or more.

Iron ball drop test: performed by dropping an iron ball of 1 g freely from a height of 1 m onto the adhesive face.

[Supplementary Note 5] The pressure-sensitive adhesive sheet according to any one of supplementary notes 1 to 4, wherein release strength of the release liner from the adhesive face of the pressure-sensitive adhesive layer is not less than 0.15 N/50 mm and not more than 5 N/50 mm.
[Supplementary Note 6] The pressure-sensitive adhesive sheet according to any one of supplementary notes 1 to 5, wherein a thickness of the pressure-sensitive adhesive layer is not less than 1 μm and not more than 500 μm.
[Supplementary Note 7] The pressure-sensitive adhesive sheet according to any one of supplementary notes 1 to 6, wherein the pressure-sensitive adhesive layer is a pressure-sensitive adhesive layer formed from an acrylic pressure-sensitive adhesive composition.
[Supplementary Note 8] The pressure-sensitive adhesive sheet according to any one of supplementary notes 1 to 7, wherein the pressure-sensitive adhesive layer has a second pressure-sensitive adhesive layer stacked on a surface opposite to the adhesive face.
[Supplementary Note 9] The pressure-sensitive adhesive sheet according to any one of supplementary notes 1 to 8, wherein the pressure-sensitive adhesive layer has a base material layer stacked on a surface opposite to the adhesive face.
[Supplementary Note 10] The pressure-sensitive adhesive sheet according to supplementary note 9, wherein a second pressure-sensitive adhesive layer is stacked on a surface of the base material layer on which the pressure-sensitive adhesive layer is not stacked.
[Supplementary Note 11] The pressure-sensitive adhesive sheet according to supplementary note 9 or 10, wherein the base material layer is formed from a polyester film.

### REFERENCE SIGNS LIST

1 Pressure-sensitive adhesive sheet
10 Pressure-sensitive adhesive layer
R1, R2 Release liner
2 Pressure-sensitive adhesive sheet
20, 21 Pressure-sensitive adhesive layer
3 Pressure-sensitive adhesive sheet
30 Pressure-sensitive adhesive layer
S1 Base material
4 Pressure-sensitive adhesive sheet
40, 41 Pressure-sensitive adhesive layer
S2 Carrier substrate
50 Temporary fixing material (substrate or pressure-sensitive adhesive sheet)
51 Electronic component
60 Pressure-sensitive adhesive sheet or substrate

1. A pressure-sensitive adhesive sheet comprising a pressure-sensitive adhesive layer having an adhesive face protected by a release liner, wherein a displacement R of water contact angles θ1 and θ2 against the adhesive face under the following conditions T1 and T2 is 5° or less:
T1: immediately after separating the release liner under an environment of 23° C.
T2: after 2 hour exposure of the adhesive face to an atmospheric environment after separating the release liner under an environment of 23° C.
θ1: water contact angle (°) of the adhesive face under T1
θ2: water contact angle (°) of the adhesive face under T2
$$Displacement R ( ° ) = θ 2 - θ 1.$$

2. The pressure-sensitive adhesive sheet according to claim 1, wherein the pressure-sensitive adhesive sheet is used for receiving an electronic component disposed on a temporary fixing material.

3. The pressure-sensitive adhesive sheet according to claim 1, wherein the pressure-sensitive adhesive sheet is to be disposed so as to face, with a gap provided therebetween, a surface of a temporary fixing material on which an electronic component is disposed, and used for receiving the electronic component.

4. The pressure-sensitive adhesive sheet according to claim 1, wherein a ratio of a sinking depth of the pressure-sensitive adhesive layer, obtained by an iron ball drop test performed on the adhesive face of the pressure-sensitive adhesive layer under the following condition, to a thickness of the pressure-sensitive adhesive layer (sinking depth/thickness×100) is 15% or more:
Iron ball drop test: performed by dropping an iron ball of 1 g freely from a height of 1 m onto the adhesive face.

5. The pressure-sensitive adhesive sheet according to claim 1, wherein release strength of the release liner from the adhesive face of the pressure-sensitive adhesive layer is not less than 0.15 N/50 mm and not more than 5 N/50 mm.

6. The pressure-sensitive adhesive sheet according to claim 1, wherein a thickness of the pressure-sensitive adhesive layer is not less than 1 μm and not more than 500 μm.

7. The pressure-sensitive adhesive sheet according to claim 1, wherein the pressure-sensitive adhesive layer is a pressure-sensitive adhesive layer formed from an acrylic pressure-sensitive adhesive composition.

8. The pressure-sensitive adhesive sheet according to claim 1, wherein the pressure-sensitive adhesive layer has a second pressure-sensitive adhesive layer stacked on a surface opposite to the adhesive face.

9. The pressure-sensitive adhesive sheet according to claim 1, wherein the pressure-sensitive adhesive layer has a base material layer stacked on a surface opposite to the adhesive face.

10. The pressure-sensitive adhesive sheet according to claim 9, wherein a second pressure-sensitive adhesive layer is stacked on a surface of the base material layer on which the pressure-sensitive adhesive layer is not stacked.

11. The pressure-sensitive adhesive sheet according to claim 9, wherein the base material layer is formed from a polyester film.
